(19) United States
(12) Patent Application Publication
(10) Pub. No.: US 2006/0091485 A1
(43) Pub. Date: May 4, 2006

(54) Piezoelectric device and manufacturing method thereof

(76) Inventor: Yoshihiro Koshido, Shiga-ken (JP)

Correspondence Address: MURATA MANUFACTURING COMPANY, LTD.;C/O KEATING & BENNETT, LLP, 8180 GREENSBORO DRIVE, SUITE 850, MCLEAN, VA, 22102, US

(21) Appl. No.: 11/294,699

(22) Filed: Dec. 5, 2005

Related U.S. Application Data
(62) Division of application No. 10/485,340, filed on Jan. 29, 2004.

(30) Foreign Application Priority Data
Jul. 31, 2002 (JP) 2002-222600
Jul. 16, 2003 (JP) 2003-198048

(51) Int. Cl. H01L 29/84

(52) U.S. Cl. 257/415

(57) ABSTRACT

A surface acoustic wave device includes a SAW element having an IDT provided on a piezoelectric substrate and electroconductive pads connected to the IDT, and a bonding substrate having electroconductive pad through holes bonded by an adhesive layer so as to face the IDT. A protective space is provided by an excitation portion protecting hollow structure for protecting a surface acoustic wave excitation portion. External terminals connected to the electroconductive pads via the electroconductive pad through holes are at disposed at positions offset from the electroconductive pad through holes.

This application is a Divisional Application of U.S. patent application Ser. No. 10/485,340 filed Jan. 29, 2004, currently pending.

### BACKGROUND OF THE INVENTION

1. Field of the Invention

The present invention relates to a piezoelectric device such as a surface acoustic wave device for use in, for example, delay lines, filters, and other suitable devices, a piezoelectric thin-film filter, and to a manufacturing method thereof, and particularly to a chip-size packaged piezoelectric device and a manufacturing method thereof.

2. Description of the Related Art

Reduction in size and weight of electronic apparatuses in recent years has led to a demand for increased functions of electronic devices. There is similar demand for reduction in size and weight of piezoelectric devices, such as surface acoustic wave filters (hereafter referred to as SAW filters) used as surface acoustic wave devices in communication devices, such as cellular telephones and other communication devices, and piezoelectric filters using piezoelectric thin-film resonators.

A piezoelectric filter includes a piezoelectric resonator having a Si substrate with openings or recesses therein, and a vibrating portion in which the upper and lower surfaces of a thin film portion having at least one or more layers of piezoelectric thin film (e.g., formed of ZnO or AlN) provided on the openings or recesses are sandwiched between at least one pair of an upper electrode and a lower electrode facing one another, or a piezoelectric resonator wherein a Si substrate does not have openings or recesses, and a space is provided between the lower electrode and the Si substrate, the piezoelectric resonator being configured in a ladder or lattice arrangement. With such piezoelectric filters, thickness-direction-wise longitudinal vibrations produced in the vibrating portion are used, such that a vibrating space must be ensured, and also the vibrating portion must be protected from moisture, dust, and other impurities.

Also, surface acoustic wave filters include a pair of comb electrodes (inter-digital transducer, hereafter abbreviated as IDT) made of a metal such as Al or other suitable metal on a piezoelectric substrate such as crystal, LiTaO3, LiNbO3, or other suitable piezoelectric substrate. With such surface acoustic wave filters, the vibrating space must be ensured at the comb electrodes and piezoelectric substrate where the surface acoustic waves are propagated. In addition, the comb electrodes must be protected from moisture, dust, and other impurities.

With the aforementioned piezoelectric filters and surface acoustic wave filters, a die bonding agent made of a ceramic, such as alumina, is applied to the bottom surface of a package, the piezoelectric filter and surface acoustic wave filter element being mounted to the package by wire bonding, and terminals within the package and element electrodes connected by die bonding, following which the package is sealed with a lid. Also, in order to reduce the size, the piezoelectric filter and surface acoustic wave filter includes electrode lands made of alumina, for example, which are provided on the bottom surface of the package, with the piezoelectric filter and surface acoustic wave filter elements being mounted on the package by die bonding via flip-chip bonding, and the package is sealed with a lid.

However, the above-described structure has a problem in that, even when the piezoelectric filter and surface acoustic wave filter elements are reduced in size, the piezoelectric filter and surface acoustic wave filter cannot be reduced in size and height unless the package is reduced in size. Also, reducing the size of the package is expensive. Further, the vibrating portions of the piezoelectric filter in particular are provided at openings or recesses in the substrate, which causes the vibrating portion to be damaged or destroyed by application of shock in the steps of dicing the element, picking up the element for mounting, die bonding, and other forces applied to the element.

In the following description, Japanese Unexamined Patent Application Publication No. 2001-94390 will be referred to as Patent Publication 1, Japanese Unexamined Patent Application Publication No. 11-150441 will be referred to as Patent Publication 2, Japanese Unexamined Patent Application Publication No. 2001-60642 will be referred to as Patent Publication 3, and Japanese Unexamined Patent Application Publication No. 2001-244785 will be referred to as Patent Publication 4.

In comparison, Patent Publication 1, Patent Publication 2, and Patent Publication 3, for example, describe mounting with bumps. According to these publications, a SAW filter is reduced in size by eliminating the space required for wiring bonding by flip-chip bonding wherein bumps provided on a base substrate and the SAW element are bonded. However, electroconductive pads corresponding to the bumps must be provided on the SAW element, and the effective area of the SAW element is reduced, such that size reduction is difficult. Also, forming bumps increases costs.

Accordingly, with Patent Publication 4, the SAW element is mounted on a base substrate via through holes provide therein which face the extraction electrodes of the SAW element, and an electroconductive agent is filled in the through holes, thereby forming an external circuit connection portion. Thus, the size of the SAW filter is reduced.

However, with the configuration described in Patent Document 4, the extraction electrodes of the SAW element and the through holes in the base substrate are always at positions facing one another, such that the positions of the external terminals provided at the through holes are fixed. Accordingly, there is a problem in that the positions of the external terminals cannot be changed.

### SUMMARY OF THE INVENTION

To overcome the problems described above, preferred embodiments of the present invention provide a surface acoustic wave element which is reduced in size, and further is produced with an improved degree of freedom regarding the positions of external terminals, and provide a manufacturing method thereof.

The piezoelectric device according to preferred embodiments of the present invention includes a piezoelectric element having at least one vibrating portion provided on a substrate and an element wiring connected to the vibrating portion, and a bonding substrate having through holes, which is bonded by an adhesive layer, so as to face the vibrating portion, the piezoelectric device includes protective space for the vibrating portion, wherein external terminals connected to the element wiring via external terminal connecting material provided in the through holes are at positions that are offset from the through holes.

According to the above-described preferred embodiment, protective space is provided for protecting the vibrating portion, such that components which increase the size of the piezoelectric devices, such as bumps and wires, are unnecessary, the corresponding space is eliminated, and a piezoelectric device having a reduced size is provided. Also, the position of the external terminals is offset from the through holes, i.e., offset from the position of the element wiring. That is to say, the position of the external terminals can be arbitrarily selected, thereby improving the degree of freedom regarding the position. Accordingly, a piezoelectric device wherein connection to external circuits is readily performed is provided.

Further, the piezoelectric device according to another preferred embodiment of the present invention includes a piezoelectric element having at least one vibrating portion provided on a substrate and an element wiring connected to the vibrating portion, and a bonding substrate having through holes, which is bonded by an adhesive layer, so as to face the vibrating portion, the piezoelectric device includes a protective space for the vibrating portion, and a first wiring between the adhesive layer and bonding substrate which is connected to the element wiring, wherein the first wiring and external terminals are connected via external terminal connecting material provided in the through holes.

According to this preferred embodiment, the element wiring and the external terminals are connected via the first wiring and the external terminal connecting material, such that the external terminals can be provided at arbitrary positions according to the position of the first wiring and the external terminal connecting material, thereby improving the degree of freedom with regard to position. Accordingly, connection with external circuits is readily and easily performed.

With the piezoelectric device according to preferred embodiments of the present invention, the first wiring preferably includes either capacitance or an inductor, in addition to the above-described configuration. This eliminates the need to separately provide capacitance or an inductor, thus the size of the piezoelectric device is further reduced.

Further, the piezoelectric device according to another preferred embodiment of the present invention includes a piezoelectric element having at least one vibrating portion provided on a substrate and an element wiring connected to the vibrating portion, and a bonding substrate having through holes, which is bonded by an adhesive layer, so as to face the vibrating portion, the piezoelectric device includes a protective space for the vibrating portion, a second wiring on the bonding substrate connected to the element wiring, and an upper insulating layer having insulating layer openings on the bonding substrate such that a portion of the second wiring is exposed, wherein the second wiring and external terminals provided on the upper insulating layer are connected via external terminal connecting material provided in the insulating layer openings.

According to this preferred embodiment, the element wiring and the external terminals are connected via the second wiring and the external terminal connecting material, such that the external terminals can be provided at arbitrary positions according to the position of the second wiring and the external terminal connecting material, thereby improving the degree of freedom with regard to position. Accordingly, connection with external circuits can be readily performed.

With the piezoelectric device according to this preferred embodiment of the present invention, in addition to the above-described configuration, the second wiring preferably includes either capacitance or an inductor. This eliminates the need to separately provide capacitance or an inductor, thus the size of the piezoelectric device is further reduced.

With the piezoelectric device according to a preferred embodiment of the present invention, in addition to the above-described configuration, the protective space is preferably ensured by the thickness of the adhesive layer.

With the piezoelectric device according to a preferred embodiment of the present invention, in addition to the above-described configuration, the protective space is preferably a recess provided in the surface of the bonding substrate facing the vibrating portions.

Also, with the piezoelectric device according to a preferred embodiment of the present invention, in addition to the above configuration, the adhesive layer is preferably made of one of thermal setting resin, thermoplastic resin, and ultraviolet setting resin.

Also, the adhesive layer is preferably made of an adhesive agent, and further includes a resin or metal layer between the adhesive layer made of the adhesive agent, and the surface acoustic wave element.

Also, the bonding substrate is preferably made of a material which can be wet-etched, such as glass, crystal, fused silica, or other suitable material.

Also, the piezoelectric element is preferably a surface acoustic wave element having vibrating portions defined by comb-shaped electrodes provided on a substrate.

Also, the piezoelectric element is preferably a piezoelectric thin-film element having a vibrating portion wherein the upper and lower surfaces of a thin film portion having at least one layer of piezoelectric thin film, provided on the openings or recesses of a substrate having openings or recesses, are sandwiched between at least one pair of an upper electrode and a lower electrode which face each other.

Also, the piezoelectric element is preferably a piezoelectric thin-film element having a vibrating portion wherein the upper and lower surfaces of a thin film portion having at least one or more layers of piezoelectric thin film, provided on a substrate, are sandwiched between at least one pair of an upper electrode and a lower electrode facing each other, and having a space between the substrate and the lower electrode at the vibrating portion.

A method for manufacturing the piezoelectric device according to another preferred embodiment of the present invention includes a piezoelectric element having at least one vibrating portion provided on a substrate and element wiring connected to the vibrating portion, and a bonding substrate having through holes, are bonded by an adhesive layer, so as to face the vibrating portion, the method including a step of forming at least one vibrating portion on the substrate and an element wiring connected to the vibrating portion to form a piezoelectric element, a step of forming through holes in the bonding substrate, a step of bonding the piezoelectric element and the bonding substrate so as to ensure a protective space for the vibrating portion with the adhesive layer, a step of forming external terminal connection material to be connected to the element wiring via the through holes, and a step of forming external terminals to be connected to the external terminal connection material.

In addition, in the step of bonding the piezoelectric element and the bonding substrate so as to ensure a protective space for the comb electrodes with the adhesive layer, positioning is preferably performed for the element wiring and the through holes.

A method for manufacturing a piezoelectric device according to another preferred embodiment of the present invention includes a piezoelectric element having at least one vibrating portion provided on a substrate and an element wiring connected to the vibrating portion, and a bonding substrate having through holes, are bonded by an adhesive layer, so as to face the vibrating portion, the method including a step of forming at least one vibrating portion on the substrate and element wiring connected to the vibrating portion to form a piezoelectric element, a step of bonding the piezoelectric element and the bonding substrate so as to ensure a protective space for the vibrating portion with the adhesive layer, a step of forming through holes in the bonding substrate, a step of forming external terminal connection material to be connected to the element wiring via the through holes, and a step of forming external terminals to be connected to the external terminal connection material.

According to the above-described method, the protective space is provided. Thus, components which increase the size of the piezoelectric devices, such as bumps and wires, are not required, such that the corresponding space is eliminated, and a piezoelectric device which has been reduced in size is provided. Further, steps of forming the bumps, the electroconductive pads corresponding therewith, wire bonding, and other steps are not required, such that the method is simplified. Also, the position of the external terminals can be formed at arbitrary positions, thereby improving the degree of freedom regarding the position. Accordingly, connection to external circuits can be made easily.

With the method for manufacturing a piezoelectric device according to various preferred embodiments of the present invention, in addition to the above-described method, recesses are preferably formed on the bonding substrate so as to ensure the protective space for the vibrating portion. Thus, space for protecting the vibrating portion is formed.

Also, with the method for manufacturing a piezoelectric device according to a preferred embodiment of the present invention, in addition to the above-described method, the through holes are preferably formed by wet etching using a resist pattern. Thus, the through holes are easily formed.

Also, with the method for manufacturing a piezoelectric device according to a preferred embodiment of the present invention, in addition to the above-described method, the through holes may be formed by laser etching or sand blasting processing. Thus, the through holes are easily formed.

Also, with the method for manufacturing a piezoelectric device according to a preferred embodiment of the present invention, in addition to the above-described method, the external terminal connection material and/or external terminals are preferably formed by metal vapor deposition.

Also, with the method for manufacturing a piezoelectric device according to a preferred embodiment of the present invention, in addition to the above-described method, the external terminal connection material and/or external terminals may be formed by printing an electroconductive paste and then baking.

Also, with the method for manufacturing a piezoelectric device according to a preferred embodiment of the present invention, in addition to the above-described method, the external terminals may be formed by printing an electroconductive paste in through holes, such that wiring is formed with the electroconductive paste.

Also, with the method for manufacturing a piezoelectric device according to a preferred embodiment of the present invention, in addition to the above-described method, a group substrate having a plurality of the piezoelectric elements is preferably formed, with the bonding substrate being bonded to the group substrate, and then diced.

According to the above-described configuration, there is almost no positional offset between the bonding substrate and the piezoelectric element, and piezoelectric devices with outstanding quality are easily mass-produced.

The bonding substrate is preferably smaller than the group substrate. Accordingly, the offset due to a difference in thermal expansion between the SAW elements and bonding substrate at the time of bonding is further reduced, and high-quality piezoelectric devices are manufactured.

Also, the piezoelectric element may be a surface acoustic wave element having vibrating portions defined by comb-shaped electrodes provided on a substrate.

Also, the piezoelectric element may be a piezoelectric thin-film element having a vibrating portion wherein the upper and lower surfaces of a thin film portion having at least one layer of piezoelectric thin film, provided on the openings or recesses of a substrate having openings or recesses, are sandwiched between at least one pair of an upper electrode and a lower electrode facing each other.

Also, the piezoelectric element may be a piezoelectric thin-film element having a vibrating portion wherein the upper and lower surfaces of a thin film portion having at least one layer of piezoelectric thin film, provided on a substrate, are sandwiched between at least one pair of an upper electrode and a lower electrode facing each other, and having a space between the substrate and the lower electrode at the vibrating portion.

The piezoelectric device according to preferred embodiments of the present invention is reduced in size, and further, the external terminals can be formed at arbitrary positions, such that the degree of freedom regarding the position is greatly improved. Accordingly, a piezoelectric device, wherein connection to external circuits is easily performed performed, is provided.

Other features, elements, characteristics, steps and advantages of the present invention will become more apparent from the following detailed description of preferred embodiments with reference to the attached drawings.

### BRIEF DESCRIPTION OF THE DRAWINGS

FIG. 1 is a cross-sectional diagram illustrating manufacturing steps of a surface acoustic wave device according to a first preferred embodiment of the present invention.

FIG. 2 is a cross-sectional diagram illustrating manufacturing steps of a surface acoustic wave device according to the first preferred embodiment of the present invention.

FIG. 3 is a cross-sectional diagram illustrating manufacturing steps of a surface acoustic wave device according to the first preferred embodiment of the present invention.

FIG. 4 is a cross-sectional diagram illustrating manufacturing steps of a surface acoustic wave device according to a second preferred embodiment of the present invention.

FIG. 5 is a cross-sectional diagram illustrating manufacturing steps of a surface acoustic wave device according to the second preferred embodiment of the present invention.

FIG. 6 is a cross-sectional diagram illustrating manufacturing steps of a surface acoustic wave device according to the second preferred embodiment of the present invention.

FIG. 7 is a cross-sectional diagram illustrating manufacturing steps of a surface acoustic wave device according to a third preferred embodiment of the present invention.

FIG. 8 is a cross-sectional diagram illustrating manufacturing steps of a surface acoustic wave device according to a fourth preferred embodiment of the present invention.

FIG. 9 is a cross-sectional diagram illustrating manufacturing steps of a surface acoustic wave device according to a fifth preferred embodiment of the present invention.

FIG. 10 is a cross-sectional diagram illustrating manufacturing steps of a surface acoustic wave device according to the fifth preferred embodiment of the present invention.

FIG. 11 is a cross-sectional diagram illustrating manufacturing steps of a surface acoustic wave device according to a sixth preferred embodiment of the present invention.

FIG. 12 is a cross-sectional diagram illustrating manufacturing steps of a surface acoustic wave device according to the sixth preferred embodiment of the present invention.

FIG. 13 is a circuit diagram of a surface acoustic wave device as a specific example of the first preferred embodiment of the present invention.

FIG. 14 is a plan view of a surface acoustic wave element in a surface acoustic wave device as a specific example of the first preferred embodiment of the present invention.

FIG. 15 is a plan view following forming a resin layer on the surface acoustic wave element shown in FIG. 14.

FIG. 16 is a plan view following attaching a bonding substrate and forming external terminals on the resin layer shown in FIG. 15.

FIG. 17 is a cross-sectional diagram of a surface acoustic wave device as a specific example of the first preferred embodiment of the present invention.

FIG. 18 is a circuit diagram of a surface acoustic wave device as a specific example of the second preferred embodiment of the present invention.

FIG. 19 is a plan view of a surface acoustic wave element in a surface acoustic wave device as a specific example of the second preferred embodiment of the present invention.

FIG. 20 is a plan view following forming a resin layer on the surface acoustic wave element shown in FIG. 19.

FIG. 21 is a plan view following attaching a bonding substrate and forming external terminals on the resin layer shown in FIG. 20.

FIG. 22 is a cross-sectional diagram of a surface acoustic wave device as a specific example of the second preferred embodiment of the present invention.

FIG. 23 is a circuit diagram of a surface acoustic wave device as a specific example of the sixth preferred embodiment of the present invention.

FIG. 24 is a plan view of a surface acoustic wave element in a surface acoustic wave device as a specific example of the sixth preferred embodiment of the present invention.

FIG. 25 is a plan view following forming a resin layer on the surface acoustic wave element shown in FIG. 24.

FIG. 26 is a plan view following forming first wiring on the resin layer shown in FIG. 25.

FIG. 27 is a plan view following attaching a bonding substrate and forming external terminals on the resin layer shown in FIG. 26.

FIG. 28 is a cross-sectional diagram of a surface acoustic wave device as a specific example of the sixth preferred embodiment of the present invention.

FIG. 29 is a cross-sectional diagram illustrating a surface acoustic wave element which is a modification of the surface acoustic wave element shown in FIG. 28.

FIG. 30 is a circuit diagram of a surface acoustic wave element as another specific example of the sixth preferred embodiment of the present invention.

FIG. 31 is a plan view of a surface acoustic wave element in another surface acoustic wave element as a specific example of the sixth preferred embodiment of the present invention.

FIG. 32 is a plan view following forming a resin layer on the surface acoustic wave element shown in FIG. 31.

FIG. 33 is a plan view following forming first wiring and wiring on the resin layer shown in FIG. 32.

FIG. 34 is a plan view following attaching a bonding substrate and forming external terminals on the resin layer shown in FIG. 33.

FIG. 35 is a circuit diagram of a surface acoustic wave device as a specific example of a seventh preferred embodiment of the present invention.

FIG. 36 is a plan view of a surface acoustic wave element in a surface acoustic wave device as a specific example of the seventh preferred embodiment of the present invention.

FIG. 37 is a plan view following forming a resin layer on the surface acoustic wave element shown in FIG. 36.

FIG. 38 is a plan view following attaching a bonding substrate on the resin layer shown in FIG. 37.

FIG. 39 is a plan view following forming second wiring on the bonding substrate shown in FIG. 38.

FIG. 40 is a plan view following forming an upper resin layer on the bonding substrate shown in FIG. 38, and forming external terminals.

FIG. 41 is a cross-sectional diagram of a surface acoustic wave element in a surface acoustic wave device as a specific example of the seventh preferred embodiment of the present invention.

FIG. 42 is a cross-sectional diagram illustrating a surface acoustic wave element which is a modification of the surface acoustic wave element shown in FIG. 41.

FIG. 43 is a circuit diagram of a surface acoustic wave element as another specific example of the seventh preferred embodiment of the present invention.

FIG. 44 is a plan view of a surface acoustic wave element in a surface acoustic wave device as another specific example of the seventh preferred embodiment of the present invention.

FIG. 45 is a plan view following forming a resin layer on the surface acoustic wave element shown in FIG. 44.

FIG. 46 is a plan view following attaching a bonding substrate on the resin layer shown in FIG. 45, and forming second wiring.

FIG. 47 is a plan view following forming an upper resin layer on the bonding substrate shown in FIG. 46, and forming external terminals.

FIG. 48 is a cross-sectional diagram of a surface acoustic wave element as another specific example of the seventh preferred embodiment of the present invention.

FIG. 49 is a circuit diagram of a piezoelectric thin-film filter as a specific example of an eighth preferred embodiment of the present invention.

FIG. 50 is a plan view of a piezoelectric thin-film element in a piezoelectric thin-film filter as a specific example of the eighth preferred embodiment of the present invention.

FIG. 51 is a cross-sectional view of the piezoelectric thin-film element shown in FIG. 50.

FIG. 52 is a plan view following forming a resin layer on the piezoelectric thin-film element shown in FIG. 50.

FIG. 53 is a plan view following attaching a bonding substrate on the resin layer shown in FIG. 52, and forming second wiring.

FIG. 54 is a plan view following forming au upper resin layer on the bonding substrate shown in FIG. 53, and forming external terminals.

FIG. 55 is a cross-sectional diagram of a piezoelectric thin-film filter as a specific example of the eighth preferred embodiment of the present invention.

FIG. 56 is a cross-sectional diagram illustrating a piezoelectric thin-film filter which is a modification of the piezoelectric thin-film filter shown in FIG. 55.

### DETAILED DESCRIPTION OF PREFERRED EMBODIMENTS

### First Preferred Embodiment

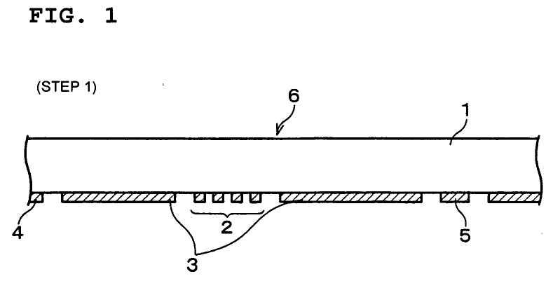

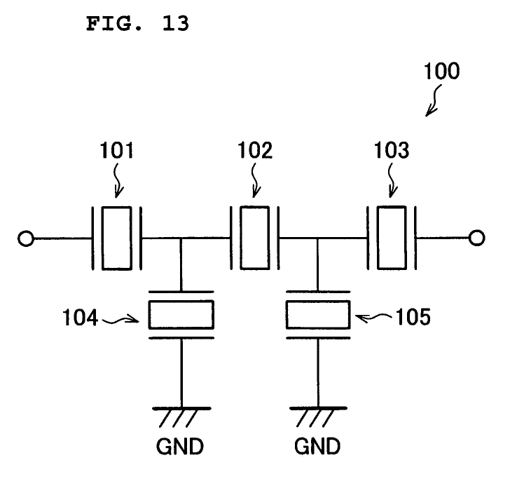

The first preferred embodiment of the present invention will now be described with reference to FIG. 1 through FIG. 3, and FIG. 13 through FIG. 17.

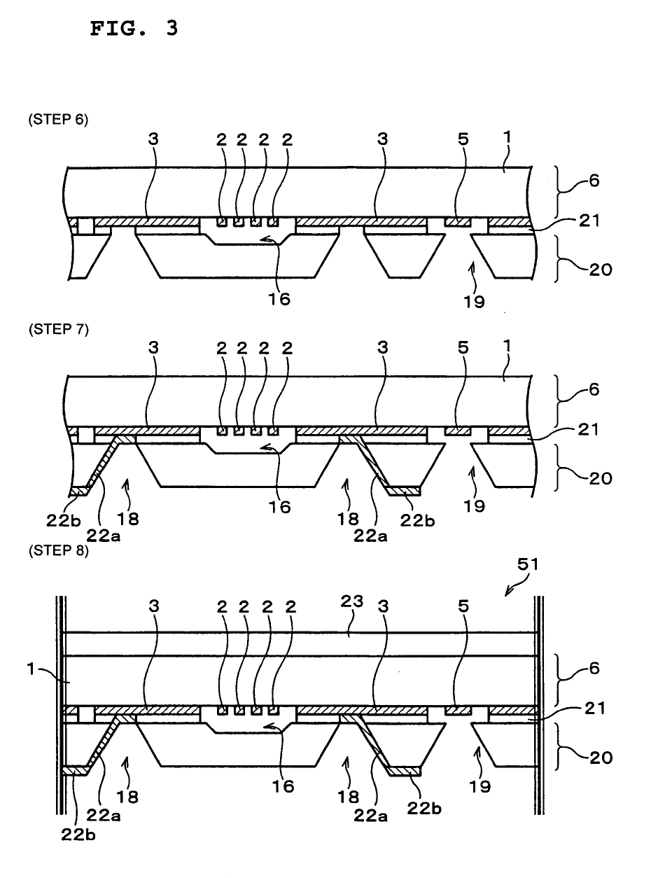

With the present preferred embodiment, a SAW filter 51 including a SAW element (piezoelectric element) 6 and a bonding substrate 20 which are bonded together with an adhesive layer 21 into a chip-size package will be described, as shown in FIG. 3. The SAW element 6 includes at least an IDT (vibrating portion) 2 and electroconductive pads (element wiring) 3 on the surface facing the bonding substrate 20. The bonding substrate 20 includes an excitation portion protecting hollow structure (recess) 16 for protecting the excitation portion for surface acoustic waves of the IDT 2 for the time of bonding with the SAW element 6 (to prevent the IDT and the bonding substrate from coming into contact), on the side surfacing the SAW element 6. The excitation portion protecting hollow structure 16 and the thickness of the adhesive layer 21 ensure a sufficient space for protecting the excitation portion for surface acoustic waves of the IDT 2 of the SAW element 6. Also, the excitation portion protecting hollow structure 16 enables the height of the SAW filter to be reduced. Further, electroconductive pad through holes 18 for external connection of the electroconductive pads 3 of the SAW element 6 are provided in the bonding substrate 20, and external terminal connection material (extraction wiring) 22a is provided and connected with external terminals 22b via the electroconductive pad through holes 18. The external terminal connection material 22a is connected with the electroconductive pads 3 via the electroconductive pad through holes 18 on a surface of the bonding substrate other than that on which the recess is provided, and is arbitrarily arranged according to the position of external terminals 22b according to the circuit with which external connection is to be made. That is to say, the degree of freedom of the position of the external terminals 22b is greatly improved. Also, formation of the external terminals 22b may be performed before, after, or simultaneous with formation of the external terminal connection material 22a.

The following is a detailed description of a manufacturing method of the aforementioned SAW filter with reference to FIG. 1 through FIG. 3.

First, as shown in FIG. 1, in Step 1, the SAW element 6 is fabricated. The IDT 2, electroconductive pads 3, reflectors (not shown), and wiring (not shown) are formed on a LiTaO3 piezoelectric substrate 1, which is preferably, about 0.35 mm thick and about 100 mm in diameter, for example. That is to say, the IDT 2, electroconductive pads 3, reflectors, and lead wiring are preferably made of Al, for example, on a LiTaO3 piezoelectric substrate 1, by a lift-off method or other suitable method using vapor deposition. Thus, the SAW element 6 is fabricated. Also, at the time of the lift-off using vapor deposition, a frame is preferably formed following the perimeter of the SAW chip (dicing line), so as to serve as a base for an airtight sealing outer frame 4 at the time of applying to the later-described bonding substrate. Also, the dicing line may be made deeper so as to also serve as the airtight sealing outer frame. Further, alignment marks 5 may also be formed for positioning at the time of bonding to the later-described bonding substrate. While the shape and size of the alignment marks 5 are not restricted in particular, substantially round shapes having a diameter of about 10 μm, for example, are used here. Also, though only one SAW element 6 is illustrated in FIG. 1, this may be a group substrate wherein multiple SAW elements 6 are provided on the piezoelectric substrate 1.

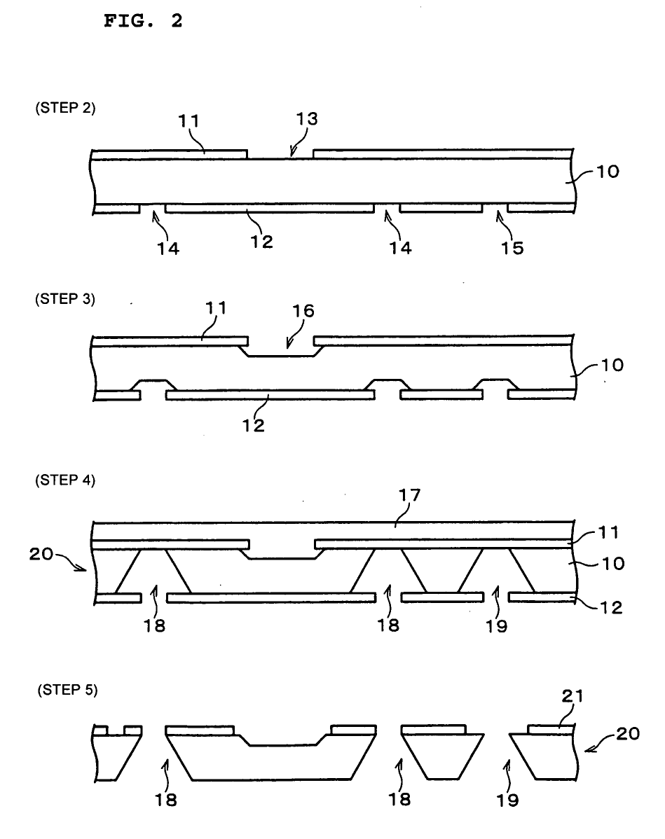

Next, the bonding substrate 20 is fabricated in Step 2 through Step 5, as shown in FIG. 2.

In Step 2, a resist pattern 11, having an opening 13 for forming a hollow structure to protect the excitation portion for surface acoustic waves of the IDT 2 is formed on one surface (the surface facing the surface of the LiTaO3 piezoelectric substrate 1 on which the IDT is formed (hereafter referred to as surface A)) of a glass substrate 10 which is about 0.10 mm thick, and about 100 mm in diameter, for example.

Further, a resist pattern 12 having openings 14 for forming through holes for external connection of the electroconductive pads 3 and an opening 15 for an alignment mark are formed on the other surface of the glass substrate 10 (hereafter referred to as surface B). Here, the opening 15 for the alignment mark is formed in a substantially round shape to match the alignment mark 5, and further, is aligned with the center of the alignment mark 5.

Next, in Step 3, both surfaces of the glass substrate 10 are half-etched by about 30 μm, for example, with hydrofluoric acid or other suitable etching solution. This forms the excitation portion protecting hollow structure 16.

Next, in Step 4, a resist pattern 17 is applied to the entire surface of the surface A of the glass substrate 10 to protect the excitation portion protecting hollow structure 16. Further, through etching is performed with hydrofluoric acid or other suitable etching solution on the surface B of the glass substrate 10 following the resist pattern 12, thereby forming the electroconductive pad through holes 18 and alignment mark through hole 19. At this time, through etching is performed from one side, such that electroconductive pad through holes 18 and alignment mark through hole 19 are formed in a tapered shape. Subsequently, the resist patterns 11, 12, and 17 are peeled off. Thus, the bonding substrate 20 is fabricated. Note that while only one bonding substrate 20 is shown in FIG. 2, a plurality may be formed on the glass substrate 10.

Next, in Step 5, an adhesive layer 21 defined by an adhesive agent is transferred onto the surface A of the bonding substrate (glass substrate 10) 20. At this time, no adhesive agent adheres to the portions of the excitation portion protecting hollow structure 16, the electroconductive pad through holes 18, and the alignment mark through hole 19. Forming the adhesive layer 21 on the bonding substrate 20 prevents adhesion of the adhesive agent to the IDT.

Next, as shown in FIG. 3, in Step 6, the SAW device 6 fabricated in Step 1 and the bonding substrate 20 having the adhesive layer 21 fabricated in Steps 2 through 5 are bonded to each other. At this time, the alignment mark 5 of the SAW element 6 and the alignment mark through hole 19 of the bonding substrate 20 are aligned. Thus, bonding is performed upon the electroconductive pads 3 of the SAW element 6 and the electroconductive pad through holes 18 of the bonding substrate 20 which are aligned. Also, the glass substrate and the LiTaO3 piezoelectric substrate have a high degree of flatness, such that temporary fixing the glass substrate to the LiTaO3 piezoelectric substrate at the time of bonding is facilitated. Also, a transparent glass substrate is used to facilitate positioning. Note that while FIG. 3 illustrates only one set of the SAW element 6 and bonding substrate 20 being bonded to each other, in practice, a plurality is formed.

Next, in Step 7, the surface B of the bonding substrate 20 is applied with a lift-off resist (not shown) having openings for desired wiring. At this time, opening are formed in the resist such that external terminals for connecting to the electroconductive pads 3 of the SAW element 6 are formed on the electroconductive pad through holes 18 of the bonding substrate (glass substrate 10) 20. The wiring pattern is formed such that the surface B of the bonding substrate 20 has an L component or a C component, for example. Metal for multi-layered structure wiring, of Au (200 nm)/Pd (100 nm)/Ti (100 nm) for example, is vapor-deposited from above the lift-off resist, and the resist is lifted off. Thus, external terminal connection material 22a is formed so as to connect the electroconductive pads 3 of the SAW element 6 to the bonding substrate 20. Also, the external terminal connection material 22a and the external electrodes 22b may be formed at the same time. Further, the formation of the external electrodes 22b may be performed before or after formation of the external terminal connection material 22a.

Next, in order to minimize the shock of mounting, in Step 8, a shock-absorbing resin layer 23 for absorbing shock is formed on the entire surface of the SAW element 6. Finally, dicing is performed at desired positions, thereby completing a SAW filter 51.

While the above-described method preferably uses a glass substrate for the bonding substrate 20, the present invention is not restricted thereto, and monocrystalline SiO2 (crystal) substrates or fused silica substrates may be used, for example. According to these substrates, wet etching is performed such that the through holes and the excitation portion protecting hollow structure are easily and inexpensively formed. Particularly, the bonding substrate 20 is preferably transparent to facilitate positioning. Also, a resin film formed of polyimide or other suitable material may be used for the bonding substrate. That is to say, the bonding substrate is an insulator, preferably with a relative permittivity lower than that of the piezoelectric substrate of the SAW element (the LiTaO3 or LiNbO3 of the piezoelectric substrate has a relative permittivity of at least about 20, so a relative permittivity of about 4 or less is preferable).

Also, the glass substrate 10 is preferably smaller than the piezoelectric substrate 1 beforehand. Thus, offset at the time of bonding, due to the difference in thermal expansion between the piezoelectric substrate of the SAW element and the glass substrate is reduced. Division into individual SAW filters is achieved by dicing.

Also, a metal film such as Ti may be formed on the surface of the piezoelectric substrate 1 on which the IDT is not formed, as a shield to prevent effects from external electromagnetic waves.

The adhesive layer 21 is preferably formed of, for example, a thermal setting resin, such as an epoxy, silicone, phenol, polyimide, polyurethane, or other suitable thermal setting resin, a thermoplastic resin such as polyphenylene sulfide or other suitable thermoplastic resin, or an ultraviolet setting resin, such that the SAW element 6 and the bonding substrate 20 are bonded by applying heat or ultraviolet rays. However, materials which generate corrosive gasses are preferably avoided.

In addition, the adhesive layer 21 may be formed of a resin layer of polyimide, novolac resin, photosensitive benzo-cyclo-butene (BCB) or other suitable resin, a metal solder layer, or a metal layer of Al, Ag, Au or other suitable metal, and an adhesive layer of an epoxy, a silicone, a polyimide, or other suitable adhesive material. Forming the metal layer at the excitation portion protecting hollow structure 16 of the bonding substrate 20 prevents the effects of external electromagnetic waves. Further, while the adhesive layer 21 is formed on the bonding substrate 20 side with the above-described method, this may be formed on the SAW element 6 side instead. Also, a configuration may be used wherein not only the adhesive layer 21, but also an unshown resin layer (insulating layer) is preferably formed on the bonding substrate side 20, with the resin layer 21 provided on the resin layer. Moreover, the resin layer may be formed on the SAW element 6 side instead of the bonding substrate 20 side, and further with the resin layer 21 provided on the resin layer.

Also, for example, resin with electroconductivity or without may be used for the shock-absorbing resin layer 23. Of these, a material having electroconductivity is preferably, such as an epoxy resin including Ag particles. The resin having electroconductivity blocks external electromagnetic waves.

Also, the method for forming the external terminal connection material 22a is not restricted to that of the above-described method. For example, electroconductive paste may be filled in the electroconductive pad through holes 18 of the bonding substrate 20, or printed with a sufficient thickens, and then baked, to form the external terminal connection material (via hole) 22a. With this method, the external terminal connection material 22a and the external electrodes 22b may be formed at the same time.

Examples of the electroconductive paste include a resin Ag paste, solder paste, low-temperature-baking Sn paste and Zn paste. Also, wiring can be formed on the bonding substrate 20 at the same time, such that the manufacturing steps are simplified.

Also, the resin used for the adhesive layer 21 is inexpensive, such that costs are reduced.

Also, the external terminal connection material 22a, or both the external terminal connection material 22a and the external electrodes 22b, may be formed by vapor deposition of a metal onto the entire surface of the surface B of the bonding substrate 20, and then etching. Also, a multi-layered structure may be formed wherein a Ti or NiCr layer is formed as a coherence layer and then an Au or Ag layer is formed for solder wettability. Also, a Pd layer or Ni layer may be formed as a dispersion preventing layer between the coherence layer and the Au or Ag layer.

Further, a surface acoustic wave filter according to a more specific example of the preferred embodiments of the present invention will be described with reference to FIG. 13 through FIG. 17. With this specific example, a case in which an upper resin layer (insulating layer) is provided in the SAW element side, and an adhesive layer is provided on the resin layer to perform bonding will be described.

FIG. 13 illustrates a circuit diagram of a surface acoustic wave filter 100 according to the specific example. The surface acoustic wave filter 100 includes surface acoustic wave resonators 101 through 105 having IDTs (vibrating portions) arranged a ladder configuration. Note that the surface acoustic wave resonators 101 through 103 are serial resonators, and the surface acoustic wave resonators 104 and 105 are parallel resonators.

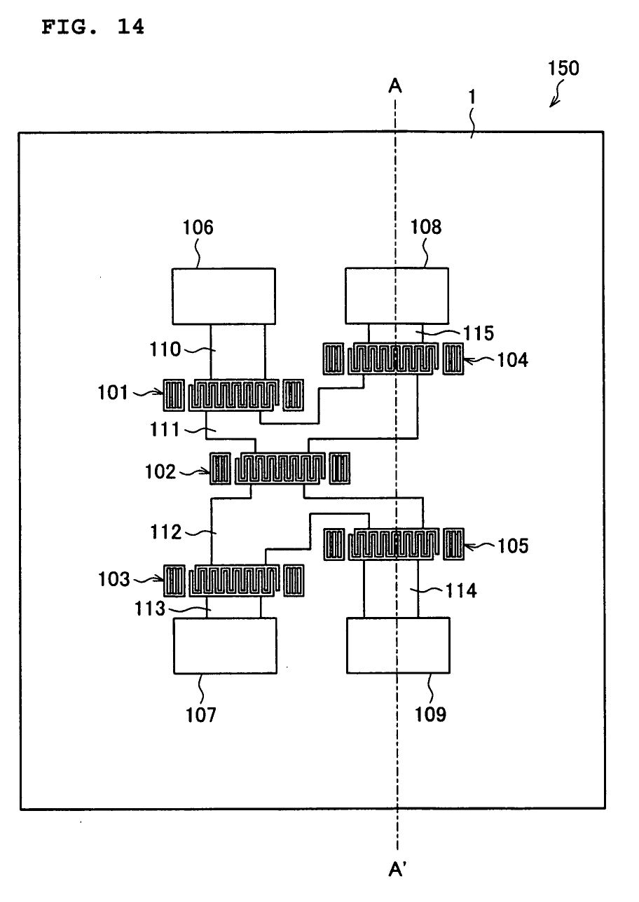

The following is a description of the method for forming the surface acoustic wave filter according to the present preferred embodiment with reference to FIG. 14 through FIG. 17, with regard to the surface acoustic wave filter 100 according to the specific example.

First, as shown in FIG. 14, surface acoustic wave resonators 101 through 105, electroconductive pads (element wiring) 106 through 109, and lead wiring (element wiring) 110 through 115 are formed on a piezoelectric substrate 1, thereby fabricating a SAW element 150.

Note that the electroconductive pad 106 is connected to the input terminal, the electroconductive pad 107 to the output terminal, and the electroconductive pads 108 and 109 are both connected to ground terminals.

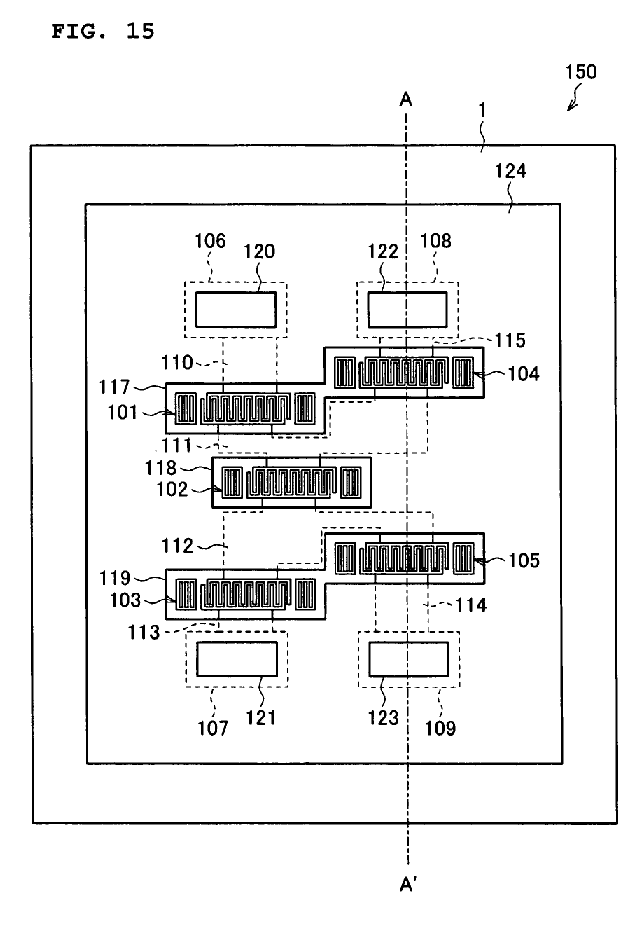

Next, as shown in FIG. 15, a resin layer 124 is formed on the SAW element 150, having resin layer openings 117 through 119 for exposing the surface acoustic wave resonators 101 through 105, and resin layer openings 120 through 123 for exposing the electroconductive pads 106 through 109. The resin layer 124 covers substantially the entire piezoelectric substrate 1. Also, an unshown adhesive layer is formed on the resin layer 124.

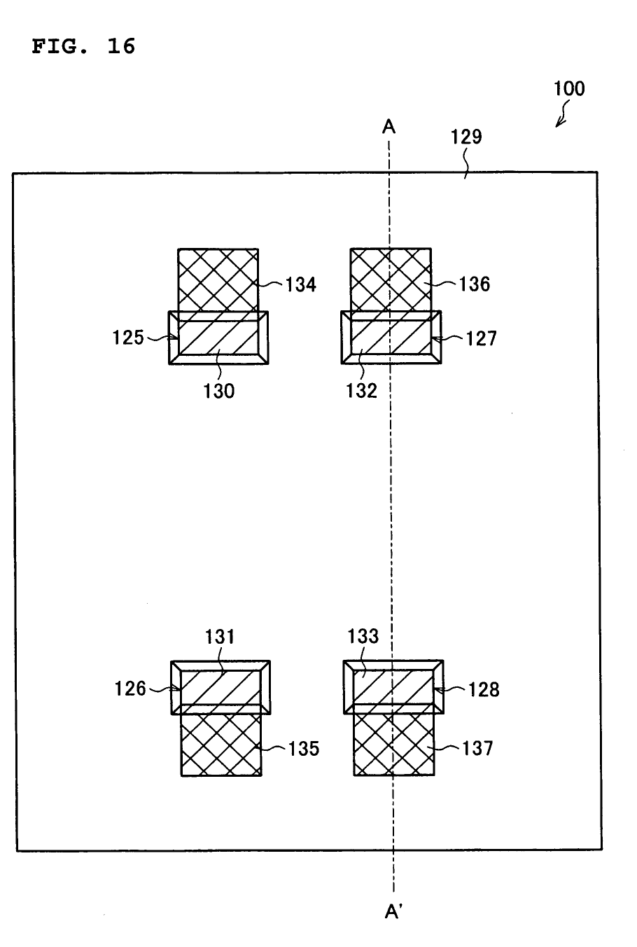

Next, as shown in FIG. 16, a bonding substrate 129 in which through holes 125 through 128 have been formed such that the electroconductive pads 106 through 109 are exposed is positioned and bonded onto the SAW element 150, thereby bonding the SAW element 150 and the bonding substrate 129. External terminal connecting material 130 through 133 connected to the respective electrode pads 106 through 109, and external terminals 134 through 137 connected to the external terminal connecting material 130 through 133, are formed via the resin layer openings 120 through 123 and the through holes 125 through 128, thereby completing the surface acoustic wave filter 100.

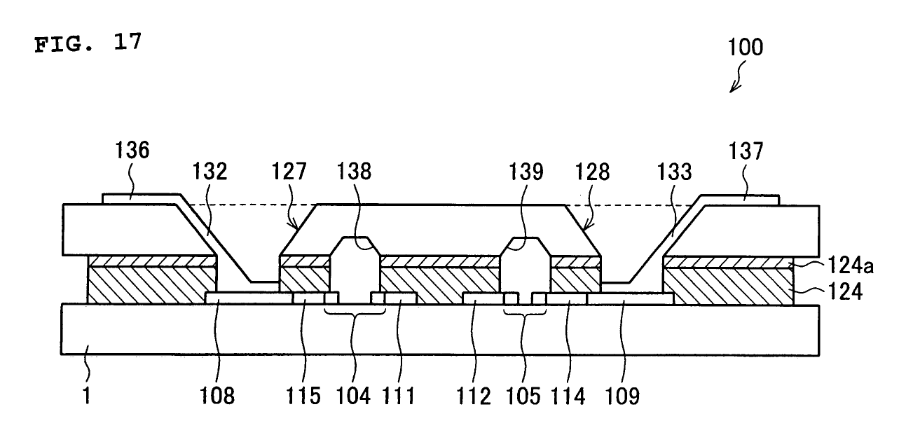

Now, a cross-sectional view along line A-A′ shown in FIG. 14 through FIG. 16 of the completed surface acoustic wave filter 100 is shown in FIG. 17.

As shown in FIG. 17, an adhesive layer 124a is formed between the resin layer 124 and the bonding substrate 129 of the surface acoustic wave filter 100. Also, recesses 138 and 139 are provided at portions of the adhesive layer 124a facing the surface acoustic wave resonators 104 and 105 of the SAW element 150. In the same manner, recesses are also formed at portions of the bonding substrate 129 facing the surface acoustic wave resonators 101 through 103.

While protective space for the surface acoustic wave resonators having the IDTs (vibrating portions) is provided by the resin layer, adhesive layer, and the recesses, it is sufficient for the protective space to be ensured by at least one of the resin layer, adhesive layer, and recesses.

### Second Preferred Embodiment

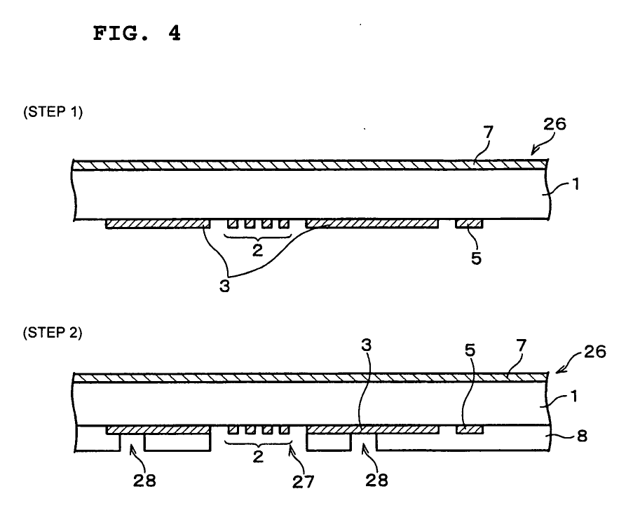

Another preferred embodiment of the present invention will be described with reference to FIG. 4 through FIG. 6 and FIG. 18 through FIG. 22. Note that in order to facilitate description, elements having the same functions as elements illustrated in the above-described first preferred embodiment will be denoted with the same reference numerals, and description thereof will be omitted.

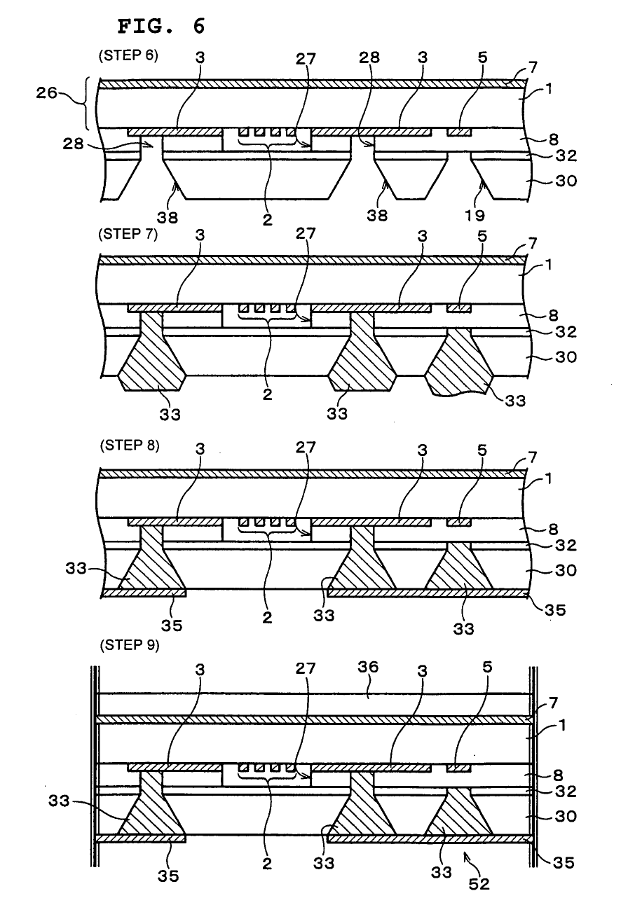

As shown in FIG. 6, with this preferred embodiment, a SAW filter 52 including a SAW element 26 and a bonding substrate 30 that are bonded together with an adhesive layer 32 will be described. With the present preferred embodiment, the excitation portion protecting hollow structure in the first preferred embodiment is not provided, and a space for protecting the IDTs is provided by the thickness of the resin layer 8.

The following is a detailed description of the method for manufacturing the above-described SAW filter, with reference to FIG. 4 through FIG. 6.

First, as shown in FIG. 4, in Step 1, the SAW element 26 is fabricated. The IDT 2, electroconductive pads 3, reflectors (not shown), and lead wiring (not shown) are formed on a LiTaO3 piezoelectric substrate 1, which is preferably about 0.35 mm thick and about 100 mm in diameter, for example. That is to say, the IDT 2, electroconductive pads 3, reflectors, and lead wiring are formed of Al, for example, on a LiTaO3 piezoelectric substrate 1 by a lift-off method using vapor deposition. A protective film 7 such as Ti or other suitable material is formed on the surface of the LiTaO3 piezoelectric substrate 1 where the IDT 2 is not formed. Also, at the time of the lift-off using vapor deposition, alignment marks 5 are formed for positioning at the time of bonding to the later-described bonding substrate. Also, though only one SAW element 26 is illustrated in FIG. 4, this may be a group substrate wherein multiple SAW elements 26 are formed on the piezoelectric substrate 1.

Next, in Step 2, an organic developing type photosensitive resin, such as photosensitive polyimide or other suitable resin, is applied onto the surface of the LiTaO3 piezoelectric substrate 1 where the IDT 2 is formed, and dried. This photosensitive resin is exposed according to a predetermined pattern, and developed, thereby forming a resin layer 8. At this time, an excitation portion protecting opening 27 for exposing the IDT 2 and reflectors and electroconductive pad openings 28 for exposing a portion of the electroconductive pads 3 for external connection are formed. The thickness of the resin layer 8 is selected such that, when added to the thickness of the adhesive layer 32 on the bonding substrate 30 to be bonded to layer, the bonding substrate 30 does not come into contact with the IDT 2. This thickness is preferably about 20 μm, for example. Also, resin pools and resin stoppers can be formed at the same time as the formation of the excitation portion protecting opening 27. Further, the half-etching required for forming the excitation portion protecting hollow structure in the later-described bonding substrate 30 is not required, thereby reducing the number of method steps.

Thus, a SAW element 26 is fabricated.

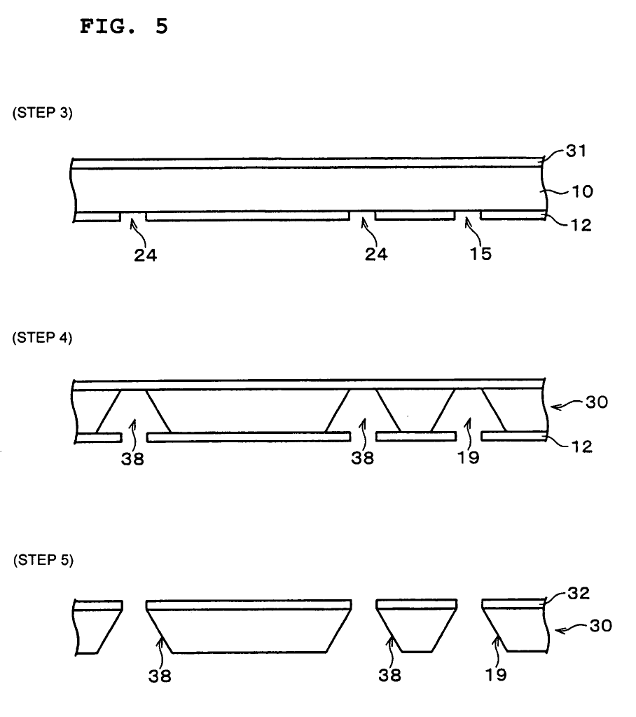

Next, as shown in FIG. 5, in Step 3 through Step 5, the bonding substrate 30 is fabricated in the same manner as in the Steps 2, 4, and 5 in the first preferred embodiment.

In Step 3, a resist 31 is formed on substantially all of one surface, the surface facing the surface of the LiTaO3 piezoelectric substrate 1 on which the IDT 2 is formed (hereafter referred to as surface A), of a glass substrate 10 which is preferably about 0.20 mm thick and about 100 mm in diameter, for example.

Further, a resist pattern 12 having electroconductive pad openings 24 matching the electroconductive pad openings 28 for conducting with the electroconductive pads 3, and an opening 15 for an alignment mark is formed on the other surface of the glass substrate 10 (hereafter referred to as surface B).

Next, in Step 4, through etching is performed with hydrofluoric acid or other suitable etching solution on the surface B of the glass substrate 10 after the resist pattern 12 is formed, thereby forming the electroconductive pad through holes 38 and alignment mark through hole 19. At this time, through etching is performed from one side, such that the electroconductive pad through holes 38 and alignment mark through hole 19 are formed in a tapered shape. Subsequently, the resist patterns 12 and 31 are peeled off. Thus, the bonding substrate 30 is fabricated. Note that while only one bonding substrate 30 is shown in FIG. 5, a plurality of bonding substrates may be formed on the glass substrate 10.

Next, in Step 5, an adhesive layer 32 defined by an adhesive agent is transferred onto the surface A of the bonding substrate (glass substrate 10) 30. In this case, the resin layer 8 which is about 20 μm thick has already been formed on the piezoelectric substrate side, such that an adhesive agent is formed on substantially the entire surface of the bonding substrate. At this time, no adhesive agent adheres to the portions of the electroconductive pad through holes 38 and the alignment mark through hole 19. While the adhesive layer 32 may be formed on the resin layer 26 of the SAW substrate 8, forming the adhesive layer 32 on the bonding substrate 30 prevents adhesion of adhesive agent to the IDT 2, and accordingly is preferable.

Next, as shown in FIG. 6, in Step 6, the SAW device 26 fabricated in Step 1 and Step 2 and the bonding substrate 30 including the adhesive layer 32 fabricated in Steps 3 through 5 are bonded to each other. At this time, the alignment mark 5 of the SAW element 26 and the alignment mark through hole 19 of the bonding substrate 30 are aligned. Thus, application is performed upon the electroconductive pads 3 of the SAW element 26 and the electroconductive pad opening 28 and the electroconductive pad through holes 38 of the bonding substrate 30 having been positioned. Also, the resin layer 8 has a sufficient thickness such that adhesion of the adhesive agent to the IDT 2 and electroconductive pads 3 is prevented.

Next, in Step 7, a resin Ag paste, for example, is printed and filled in the electroconductive pad through holes 38 and the alignment mark through hole 19, and baked to thereby form metal filled portions 33. The adhesive layer 32 can also be hardened at the same time. Also, in the event that a photosensitive resin is used for the resin layer 8, this photosensitive resin can be hardened. Further, the unnecessary portions of the metal filled portions 33 are removed by grinding, for example.

Next, in Step 8, a resin Ag paste, for example, is printed in a desired pattern, and baked, thereby forming external terminals 35 connected to the metal filled portions (external terminal connecting material) 33. At the time of this printing, wiring may be formed on the bonding substrate 30 so as to have an L component or a C component. Also, the metal filled portions 33 and the external terminals 35 may be printed and formed at the same time.

Next, in order to minimize the shock of mounting, in Step 9, a shock-absorbing resin layer 36 for absorbing shock is formed on substantially the entire surface of the protective film 7 formed on the SAW element 6. Finally, dicing is performed at desired positions to thereby complete a SAW filter 52.

As described above, with the completed SAW filter, the surface acoustic wave excitation portions (vibrating portions), such as the IDT 2, is protected by the space formed by the excitation portion protecting opening 27 formed in the resin layer 8 and the adhesive layer 32.

Also, the external terminals 35 extend from the metal filled portions 33 of the bonding substrate, and can be arbitrarily positioned according to the circuit to be externally connected to, i.e., the degree of freedom regarding the position of the external terminals 35 is greatly improved.

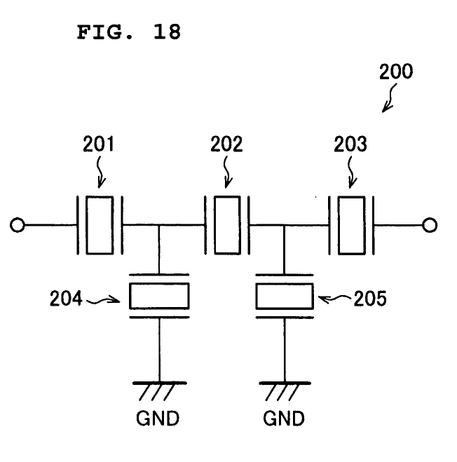

Further, a surface acoustic wave filter according to a more specific example of the present preferred embodiment of the present invention will be described with reference to FIG. 18 through FIG. 22.

FIG. 18 illustrates a circuit diagram of a surface acoustic wave filter 200 according to the specific example. The surface acoustic wave filter 200 includes surface acoustic wave resonators 201 through 205 having IDTs (vibrating portions) arranged in a ladder configuration. Note that the surface acoustic wave resonators 201 through 203 are serial resonators, and the surface acoustic wave resonators 204 and 205 are parallel resonators.

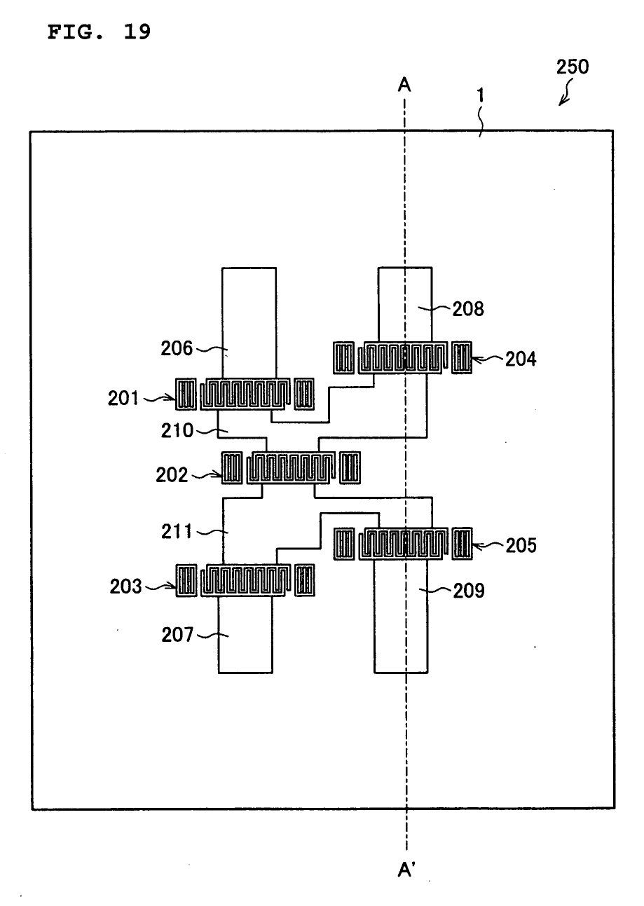

The following is a description of the method for forming the surface acoustic wave filter according to the present preferred embodiment with reference to FIG. 19 through FIG. 21, with regard to the surface acoustic wave filter 200 according to the specific example.

First, as shown in FIG. 19, surface acoustic wave resonators 201 through 205 and lead wiring (element wiring) 206 through 211 are formed on a piezoelectric substrate 1, thereby fabricating a SAW element 250.

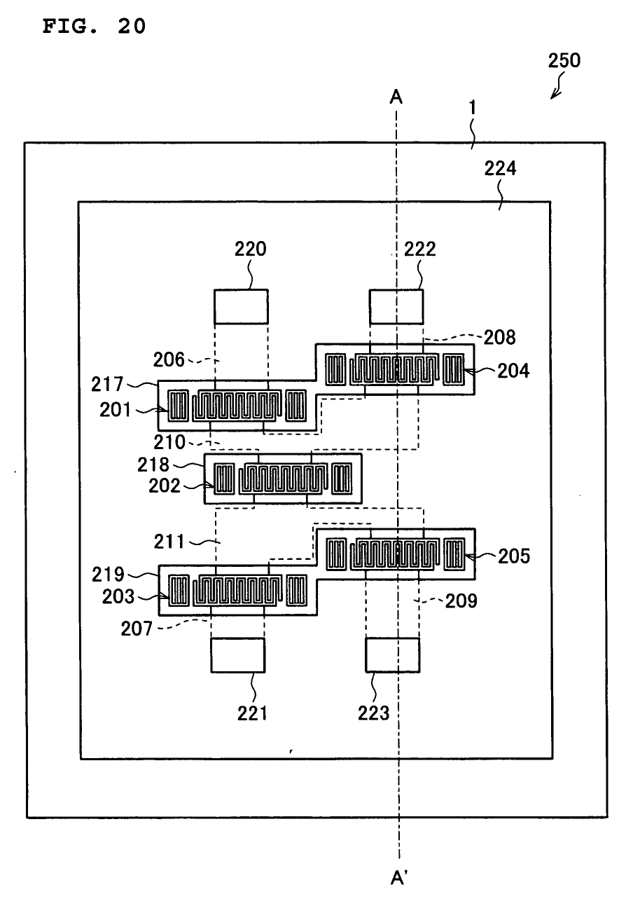

Next, as shown in FIG. 20, a resin layer 224 is formed on the SAW element 250, having resin layer openings 217 through 219 for exposing the surface acoustic wave resonators 201 through 205, and resin layer openings 220 through 223 for exposing a portion of the lead wiring 206 through 211. The resin layer 224 covers substantially the entire piezoelectric substrate 1.

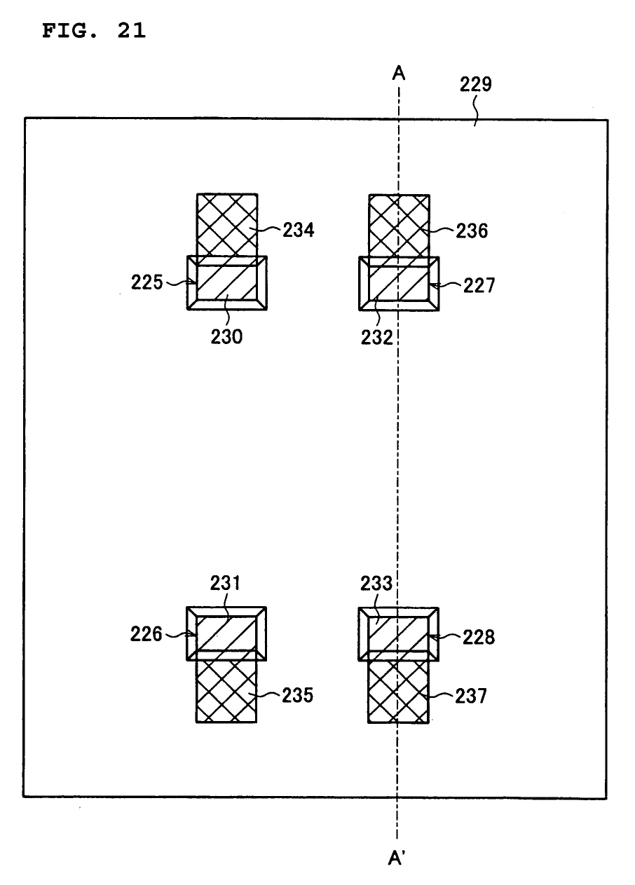

Next, as shown in FIG. 21, a bonding substrate 229 on which through holes 225 through 228 have been formed so that the lead wiring 206 through 209 is exposed is positioned and bonded onto the SAW element 250, thereby bonding the SAW element 250 and the bonding substrate 229. At this time, an unshown adhesive layer is formed on the bonding substrate 229. External terminal connecting material 230 through 233 connecting to the respective lead wiring 206 through 209, and external terminals 234 through 237 connected to the external terminal connecting material 230 through 233, are formed via the resin layer openings 220 through 223 and the through holes 225 through 228, thereby completing the surface acoustic wave filter 200.

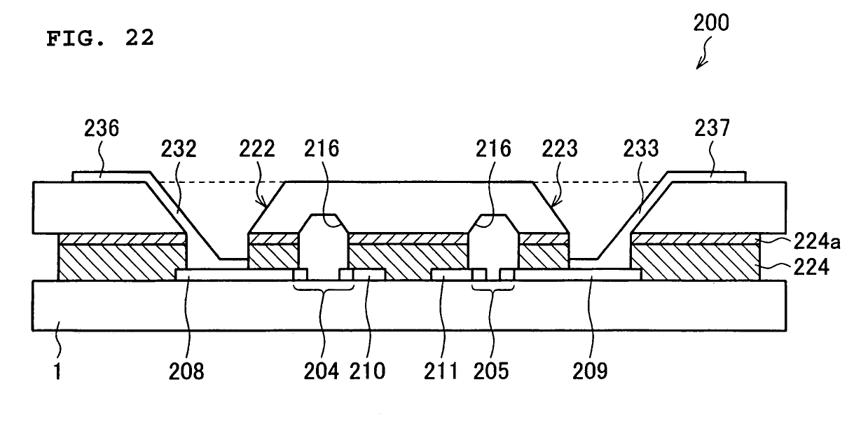

Now, a cross-sectional view along line A-A′ shown in FIG. 19 through FIG. 21 of the completed surface acoustic wave filter 200 is shown in FIG. 22.

As shown in FIG. 22, an adhesive layer 224a is formed between the resin layer 224 and the bonding substrate 229 of the surface acoustic wave filter 200. Also, with regard to the surface acoustic wave resonators 204 and 205 of the SAW element 250, a protective space for the IDTs of the surface acoustic wave resonators is provided by the thickness of the resin layer 224. In the same manner, with regard to the surface acoustic wave resonators 201 through 203, a protective space for the IDTs of the surface acoustic wave resonators is provided by the thickness of the resin layer.

While a protective space for the surface acoustic wave resonators having the IDTs (vibrating portions) is provided by the resin layer, adhesive layer, and the recesses in the above-described preferred embodiment, it is sufficient for the protective space to be provided by at least one of the resin layer, adhesive layer, and recesses.

### Third Preferred Embodiment

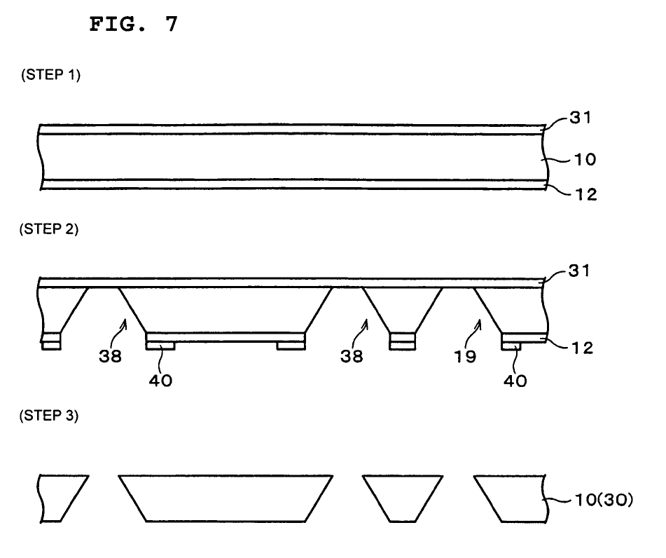

Yet another preferred embodiment of the present invention will be described with reference to FIG. 7. Note that in order to facilitate description, elements having the same functions as elements illustrated in the above-described first and second preferred embodiments will be denoted with the same reference numerals, and description thereof will be omitted.

With the present preferred embodiment, the electroconductive pad through holes 38 and the alignment mark through hole 19 in the bonding substrate 30 in the above-described second preferred embodiment are formed by laser.

That is to say, the bonding substrate 30 is fabricated by replacing Step 3 and Step 4 in the second preferred embodiment with Step 1 through Step 3 shown in FIG. 7. In Step 3 of the second preferred embodiment, the resist pattern 12 is formed on substantially the entire surface without using photolithography (Step 1). In Step 4, etching is performed by laser, thereby forming the electroconductive pad through holes 38 and the alignment mark through hole 19 (Step 2). Thus, the photolithography step is omitted, and costs are reduced. Also, the holes are tapered by controlling the power of the laser. While fused matter called dross 40 adheres around the electroconductive pad through holes 38 and the alignment mark through hole 19 due to the laser, this can be easily removed along with the resist pattern 12 in Step 3, such that the number of steps is not increased. Note that the dross may be removed by lightly etching in Step 2. Note that while only one bonding substrate 30 is shown in FIG. 7, a plurality of bonding substrates may be formed on the glass substrate 10.

Subsequently, the SAW filter is manufactured according to Step 5 of the second preferred embodiment.

When etching with the laser is performed, a sapphire (Al2O3 monocrystal) substrate, MgF substrate, MgO substrate, LiF substrate, CaF2 substrate, BaF substrate, or other suitable substrate may be used instead of the glass substrate 10.

Also, instead of etching with laser, sandblasting processing may be performed to form the electroconductive pad through holes 38 and the alignment mark through hole 19.

### Fourth Preferred Embodiment

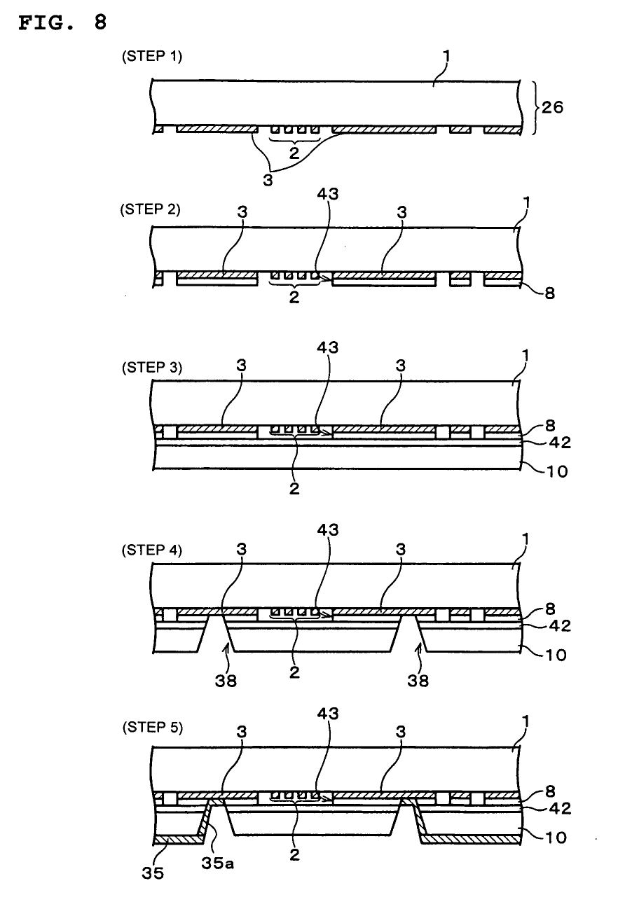

Another preferred embodiment of the present invention will be described with reference to FIG. 8. Note that in order to facilitate description, elements having the same functions as elements illustrated in the above-described first through third preferred embodiments will be denoted with the same reference numerals, and description thereof will be omitted.

With the present preferred embodiment, as shown in FIG. 8, the electroconductive pad through holes 38 and the alignment mark through hole 19 in the bonding substrate 30 in the above-described second preferred embodiment are formed by laser, following adhesion to the SAW element 26.

That is, in Step 1, as with Step 1 in the second preferred embodiment, the SAW element 26 is fabricated wherein the IDT 2, electroconductive pads 3, reflectors (not shown), and lead wiring (not shown) are formed on a LiTaO3 piezoelectric substrate 1. However, there is no need to form the alignment mark in the present preferred embodiment. Also, though only one SAW element 26 is illustrated in FIG. 8, this may be a group substrate wherein multiple SAW elements 26 are formed on the piezoelectric substrate 1.

Next, in Step 2, as with Step 2 in the second preferred embodiment, a resin layer 8 is formed on the SAW element 26. The resin layer 8 can be formed by applying a photosensitive resin of an organic developing type such as photosensitive polyimide or other suitable resin, dried, and then exposed and developed. At this time, a space (excitation portion protecting opening 43) for protecting the surface acoustic wave excitation portion such as the IDT 2 is provided. The thickness of this resin layer 8 is preferably about 20 μm, for example.

Next, in Step 3, the resin layer 8 of the SAW element 26, and the glass substrate 10 with an adhesive layer 42 formed on substantially the entire surface thereof are bonded. There is no need here to position the glass substrate 10.

Next, in Step 4, the glass substrate 10 and the adhesive layer 42 are etched by laser, thereby forming the electroconductive pad through holes 38. This exposes the electroconductive pads 3.

While dross (not shown) is generated by the laser etching, this can be removed by half-etching with hydrofluoric acid, if necessary.

Next, in Step 5, as illustrated in the first preferred embodiment, external terminal connecting material (extraction wiring) 35a to be connected with the electroconductive pads 3 via the electroconductive pad through holes 38 is formed, and external terminals 35 are formed so as to be in contact with the external terminal connecting material 35a.

Finally, dicing is performed at desired positions, thereby completing a SAW filter.

As described above, with the above-described method, positioning of the glass substrate 10 in Step 3 is unnecessary which facilitates manufacturing.

### Fifth Preferred Embodiment

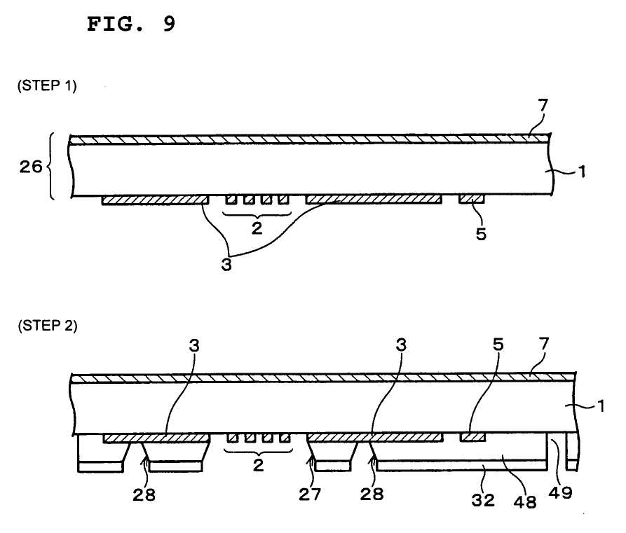

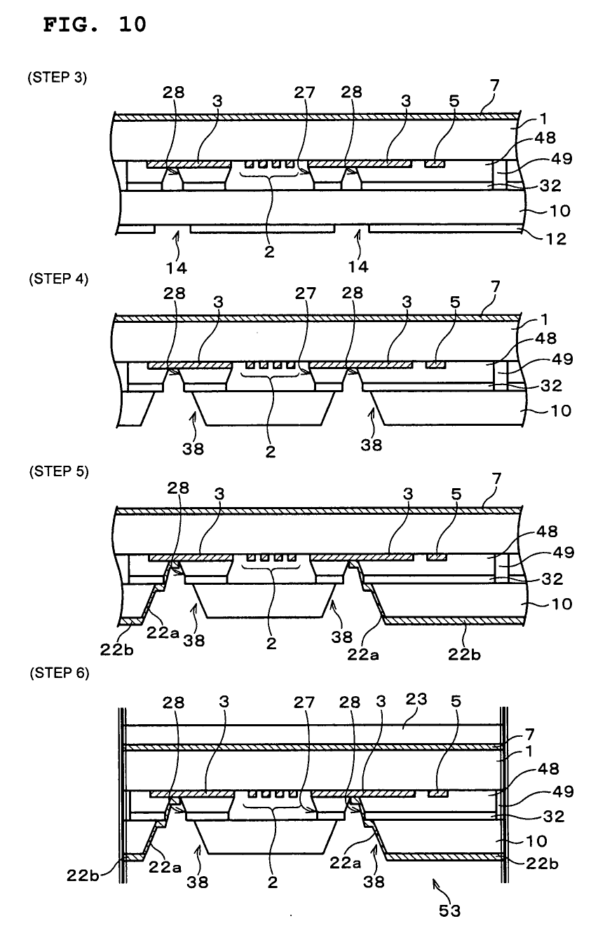

Another preferred embodiment of the present invention will be described with reference to FIG. 9 and FIG. 10. Note that in order to facilitate description, elements having the same functions as elements illustrated in the above-described first through fourth preferred embodiments will be denoted with the same reference numerals, and description thereof will be omitted.

The present preferred embodiment is an example wherein, as shown in FIG. 10, the SAW element 26 in the second preferred embodiment is provided with an adhesive layer 32 and bonded with the glass substrate 10, followed by the electroconductive pad through holes 38 being formed in the glass substrate 10.

That is, as shown in FIG. 9, in Step 1, as with Step 1 of the first preferred embodiment, a SAW element 26 having the IDT 2, electroconductive pads 3, reflectors (not shown), the alignment mark 5, and lead wiring (not shown) formed of Al on a LiTaO3 piezoelectric substrate 1, for example, is fabricated. Subsequently, Ti (20 nm) and Au (100 nm), for example, are deposited (not shown) on the electroconductive pads by the lift-off method. With the present preferred embodiment, a protective film 7 of Ti is formed on the LiTaO3 piezoelectric substrate 1. Although only one SAW element 26 is illustrated in FIG. 9, this may be a group substrate wherein multiple SAW elements are on the piezoelectric substrate 1.

Next, in Step 2, a photosensitive resin such as photosensitive polyimide or other suitable photosensitive resin is applied to a thickness of about 15 μm, for example, and dried. This photosensitive resin is further exposed and developed to thereby form a resin layer 48 having an excitation portion protecting opening 27 for protecting the IDT 2 and reflectors, electroconductive pad openings 28, and a dicing line opening 49. The exposing conditions are optimized at this time such that the openings have tapered shapes. Forming the dicing line opening 49 as described above suppresses clogging at the time of dicing. Also, the dicing line opening 49 is preferably approximately equal to the width of the dicing blade used for dicing. Thus, the protrusions of the glass are not damaged following dicing. Next, the adhesive layer 32 is transferred to the resin layer 48.

Next, as shown in FIG. 10, in Step 3, the glass substrate 10 is bonded to the adhesive layer 32, and the adhesive layer 32 is hardened. This bonding does not require positioning since no patterns are formed on the glass substrate 10. This glass substrate 10 is a glass substrate that is about 150 μm by about 100 mm, for example. Further, a resist pattern 12 for forming through holes for exposing the electroconductive pads 3 is formed on the glass substrate 10. Openings 14 for exposing the electroconductive pads 3 are formed in the resist pattern 12. The openings 14 are larger than the electroconductive pad openings 28. Thus, formation of an overhanging shape between the through holes to be formed later and the electroconductive pad openings 28 (mushroom-shaped, i.e., a shape wherein the through hole portion on the glass substrate 10 side is smaller than the electroconductive pad openings 28) is prevented. Accordingly, formation of the external terminals at a later time is facilitated. When forming the external terminals by vapor deposition, in particular, breakage of the external terminals is prevented.

Next, in Step 4, the tapered electroconductive pad through holes 38 are formed by wet etching with hydrofluoric acid or other suitable etching solution. At this time, Au has been layered on the electroconductive pads 3, such that corrosion due to the hydrofluoric acid is prevented. Also, forming a Pt layer instead of Au prevents corrosion by the hydrofluoric acid in the same manner. Also, the protective film 7 also functions as a protective film when etching is used to form the electroconductive pad through holes 38.

Next, in Step 5, a negative photo-resist is applied on the glass substrate 10, dried, further exposed and developed to thereby form a reverse-tapered resist pattern (not shown) for lift-off, having openings at the electroconductive pad through holes 38 and external terminal formation portions. In this manner, a negative photo-resist is used, so as to prevent resist residue at the electroconductive pad through holes 38, and further, reverse-tapered shapes are formed. Then, vapor deposition of Au (100 nm)/Ti (20 nm)/Ni (500 nm)/Ti (20 nm) is performed in that order, so as to form external terminal connection material 22a and external terminals 22b at the same time, and then the resist pattern is removed.

Next, in Step 6, to alleviate the shock of mounting, a shock-absorbing resin layer 23 for absorbing shock is formed on substantially the entire surface of the metal protective film 7 formed on the LiTaO3 piezoelectric substrate 1. Finally, dicing is performed at desired positions to thereby complete a SAW filter 53.

### Sixth Preferred Embodiment

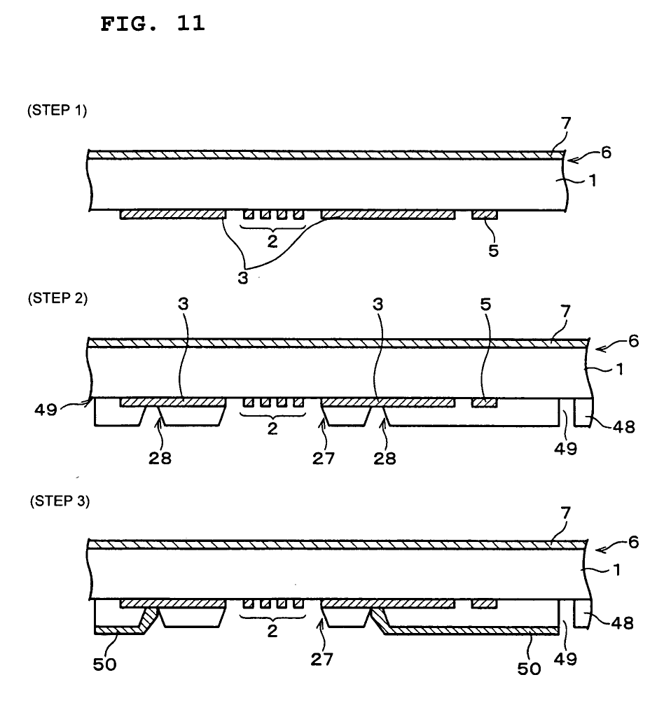

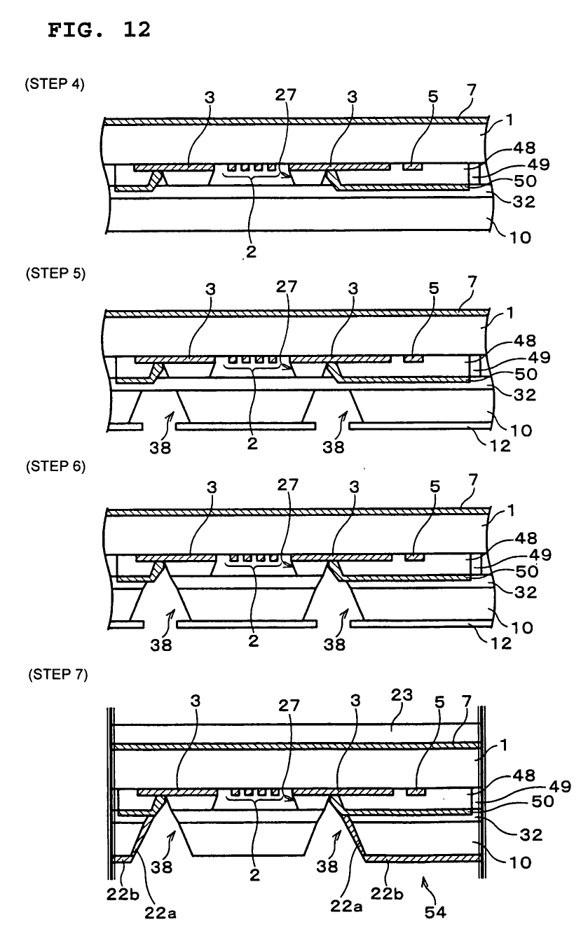

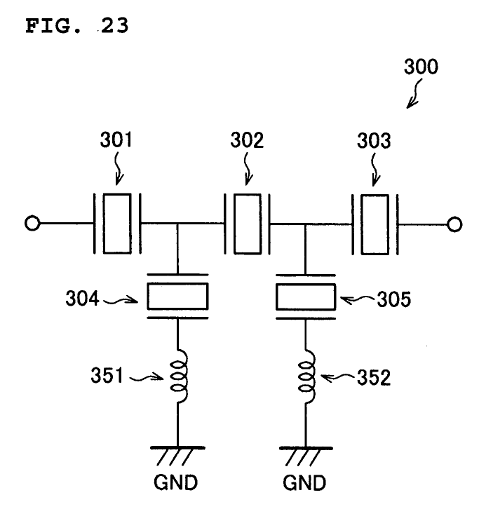

Another preferred embodiment of the present invention will be described with reference to FIG. 11 and FIG. 12, and FIG. 23 through FIG. 34. Note that in order to facilitate description, elements having the same functions as elements illustrated in the above-described first through fifth preferred embodiments will be denoted with the same reference numerals, and description thereof will be omitted.

The present preferred embodiment is an example wherein, as shown in FIG. 12, a first wiring (extraction wiring) 50 is formed on the resin layer 48 as in the fifth preferred embodiment.

That is, as shown in FIG. 11, in Step 1, as with Step 1 of the fifth preferred embodiment, a SAW element 6 having the IDT 2, electroconductive pads 3, reflectors (not shown), the alignment mark 5, and wiring (not shown) formed of Al on a LiTaO3 piezoelectric substrate 1 is fabricated. Subsequently, Ti (20 nm) and Au (100 nm) are deposited (not shown) on the electroconductive pads 3 by the lift-off method. With the present preferred embodiment, a protective film 7 of Ti or other suitable material is formed on the LiTaO3 piezoelectric substrate 1. Also, though only one SAW element 6 is illustrated in FIG. 11, this may be a group substrate wherein multiple SAW elements 6 are on the piezoelectric substrate 1.

Next, in Step 2, a photosensitive resin, such as photosensitive polyimide or other suitable photosensitive resin, is applied to a thickness of about 15 μm, and dried. This photosensitive resin is further exposed and developed, thereby forming a resin layer 48 having an excitation portion protecting opening 27 for protecting the IDT 2 and reflectors, electroconductive pad openings 28, and a dicing line opening 49. The exposing conditions are optimized such that the openings have tapered shapes. Forming the dicing line opening 49 as described above suppresses clogging at the time of dicing. Also, the dicing line opening 49 is preferably approximately equal to the width of the dicing blade used for dicing. Thus, the protrusions of the glass are not damaged following dicing.

Next, in Step 3, first wiring 50 connected to the electroconductive pads 3 is formed on the resin layer 48 by the lift-off method, in the same manner as with the electroconductive pads. The first wiring 50 may include an L component or a C component. Also, the connection portion with the electroconductive pads 3 is extended by the first wiring 50. Thus, the through holes to be formed later are formed only to expose the first wiring 50, thereby enabling the external terminals to be freely positioned.

Next, as shown in FIG. 12, in Step 4, the adhesive layer 32 is formed on the glass substrate 10, bonded to the SAW element 6, and hardened. This bonding does not require positioning since no patterns are formed on the glass substrate 10. This glass substrate 10 is a glass substrate that is preferably about 150 μm by about 100 mm, for example.

Further, in Step 5, a resist pattern 12 for forming through holes for exposing the first wiring 50 is formed on the glass substrate 10. Openings for exposing the first wiring 50 are formed in the resist pattern 12. Next, the tapered electroconductive pad through holes 38 are formed by wet etching with hydrofluoric acid or other suitable etching solution. The adhesive layer 32 is formed on substantially the entire surface of the glass substrate 10, such that the adhesive layer 32 is not etched.

Next, in Step 6, the adhesive layer 32 is etched with fuming nitric acid, an organic solvent, or other suitable etching solution. At this time, Au has been layered on the electroconductive pads 3 and the first wiring 50, such that corrosion caused by the hydrofluoric acid is prevented. Also, forming a Pt layer instead of Au prevents corrosion by the hydrofluoric acid in the same manner. Also, the protective film 7 also functions as a protective film against etching at the time of forming the electroconductive pad through holes 38.

Also, laser etching or sandblasting processing may be performed instead of the Steps 5 and 6. With etching with a laser, substantially the entire surface of the glass substrate 10 is coated with a resist, and then etched with a laser. This eliminates the need to form a resist pattern, and further, etching of the adhesive layer 32 can be performed at the same time. Hydrofluoric acid processing is then performed. This hydrofluoric acid processing is for removing fused material called dross.

Next, in Step 7, external terminal connection material 22a and external terminals 22b are formed by printing Au-Sn solder through the electroconductive pad through holes 38, and treating with heat. Next, in order to minimize the shock of mounting, a shock-absorbing resin layer 23 for absorbing shock is formed on substantially the entire surface of the metal protective film 7 formed on the LiTaO3 piezoelectric substrate 1. Finally, dicing is performed at desired positions to thereby complete a SAW filter 54.

Further, a surface acoustic wave filter according to a more specific example of the preferred embodiment of the present invention will be described with reference to FIG. 23 through FIG. 28.

FIG. 23 illustrates a circuit diagram of a surface acoustic wave filter 300 according to the specific example. The surface acoustic wave filter 300 includes surface acoustic wave resonators 301 through 305 having IDTs (vibrating portions) arranged in a ladder configuration. Note that the surface acoustic wave resonators 301 through 303 are serial resonators, and the surface acoustic wave resonators 304 and 305 are parallel resonators, with inductors 351 and 352 being serially connected to the surface acoustic wave resonators 304 and 305.

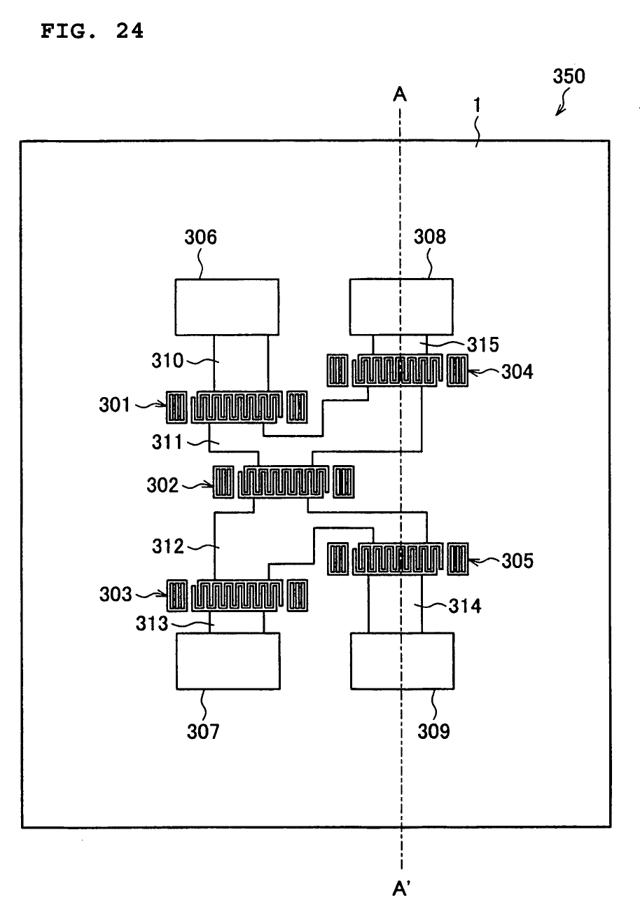

The following is a description with reference to FIG. 24 through FIG. 28, with regard to the surface acoustic wave filter 300 according to the above-described specific example.

First, as shown in FIG. 24, surface acoustic wave resonators 301 through 305, electroconductive pads (element wiring) 306 through 309, and lead wiring (element wiring) 310 through 315 are formed on a piezoelectric substrate 1, thereby fabricating a SAW element 350.

Next, as shown in FIG. 25, a resin layer 324 is formed on the SAW element 350, having resin layer openings 317 through 319 for exposing the surface acoustic wave resonators 301 through 305, and resin layer openings 320 through 323 where the electroconductive pads 306 through 309 are exposed. The resin layer 324 preferably covers substantially the entire piezoelectric substrate 1.

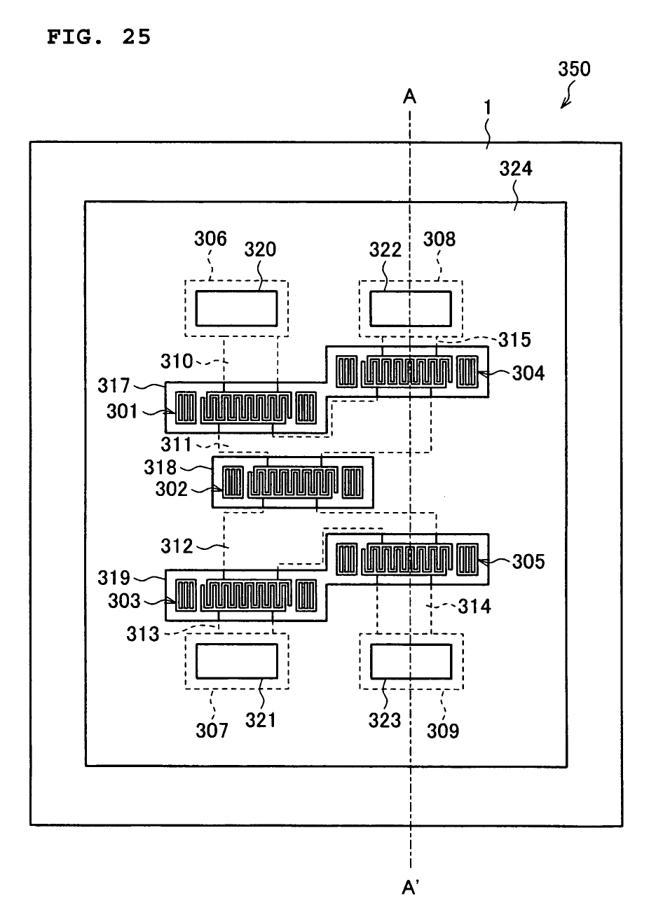

Next, as shown in FIG. 26, first wiring 361 through 364, connected to the electroconductive pads 306 through 309 via the resin openings 320 through 323, is formed. Note that the first wiring 363 and 364 is formed with inductors L. The inductors L on the first wiring 363 and 364 correspond to the above-described inductors 351 and 352. While the first wiring includes inductors L in the above description, electrodes may be formed in comb shapes to provide the first wiring with a capacitance C.

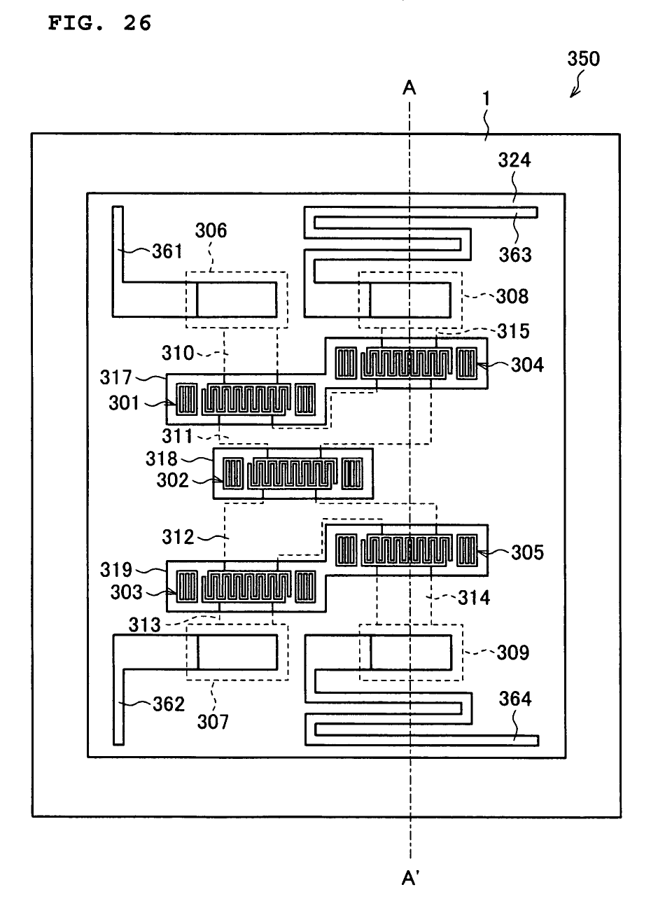

Next, as shown in FIG. 27, the bonding substrate 329 in which through holes 325 through 328 have been formed is positioned and bonded onto the resin layer 324 such that the ends of the first wiring 361 through 364 are exposed, and the SAW element 350 and the bonding substrate 329 are bonded via an unshown adhesive layer. External terminals 340 through 343 are then formed so as to be connected to the electroconductive pads 306 through 309 via the through holes 325 through 328, thereby completing the surface acoustic wave filter 300. The portions of the external terminals 340 through 343 which are formed at the through holes 325 through 328 define external terminal connecting material. That is to say, the external terminals 340 through 343 are configured such that the external terminal connecting material and the external terminals are integrally formed.

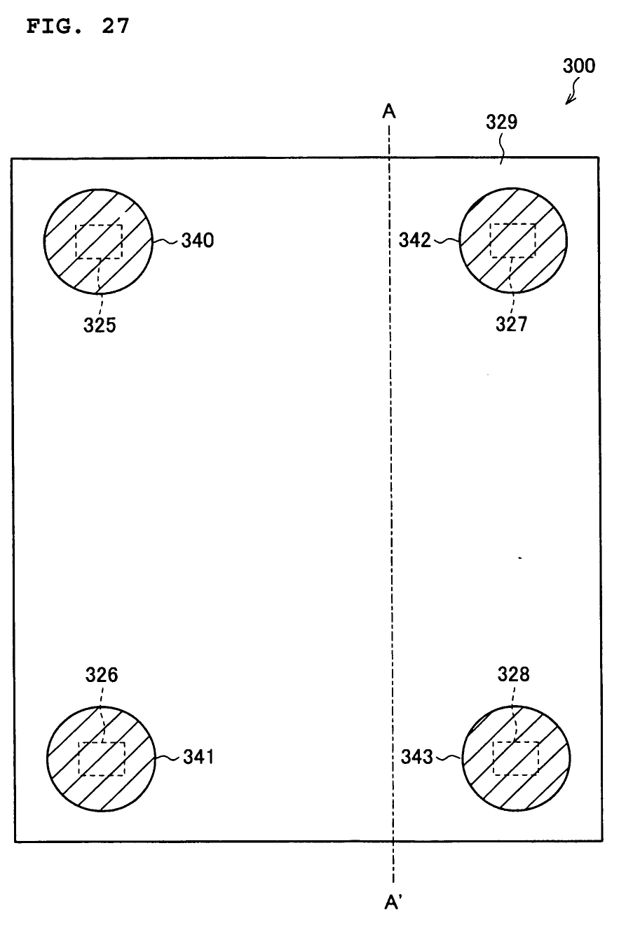

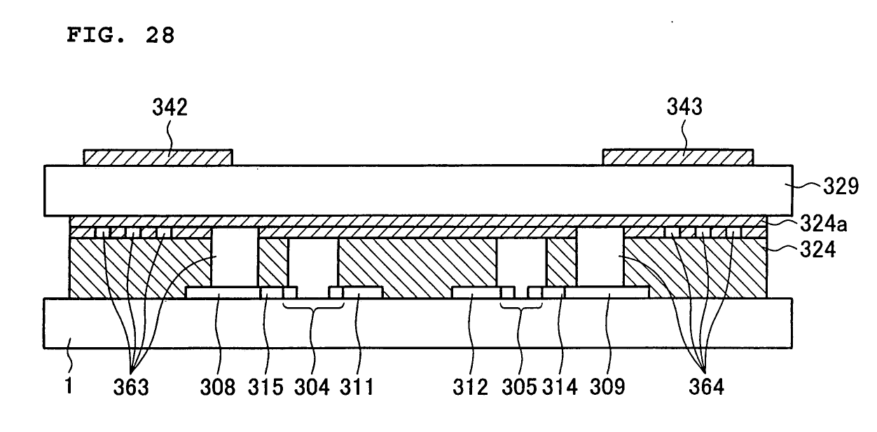

Now, a cross-sectional view along line A-A′ shown in FIG. 24 through FIG. 27 of the completed surface acoustic wave filter 300 is shown in FIG. 28.

As shown in FIG. 28, an adhesive layer 324a is formed between the resin layer 324 and the bonding substrate 329 of the surface acoustic wave filter 300. Also, for the surface acoustic wave resonators 304 and 305 of the SAW element 350, a protective space for the IDTs of the surface acoustic wave resonators is provided by the thickness of the resin layer 324. In the same manner, for the surface acoustic wave resonators 301 through 305, a protective space for the IDTs of the surface acoustic wave resonators is ensured by the thickness of the resin layer.

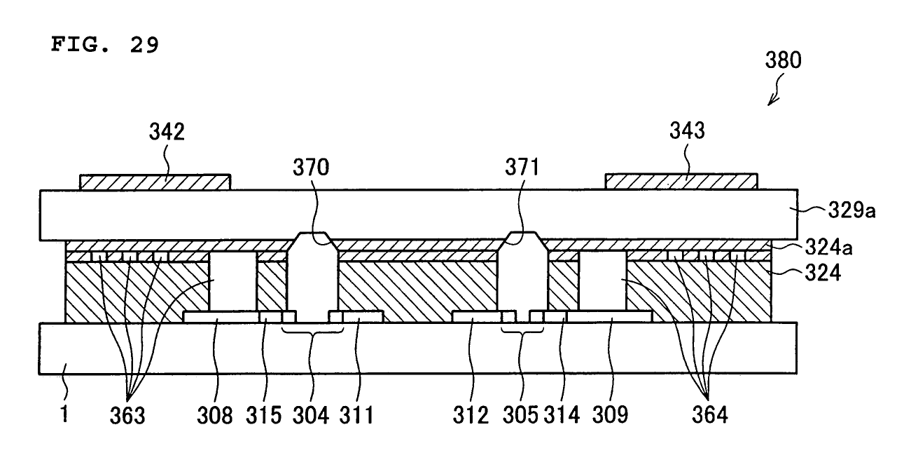

Further, a surface acoustic wave filter 380, which is a modification of the above-described surface acoustic wave filter 300, will be described with reference to FIG. 29. The surface acoustic wave filter 380 includes recesses 370 and 371 that are provided at portions facing the surface acoustic wave resonators 304 and 305 on the bonding substrate 329 of the surface acoustic wave filter 300. Moreover, recesses are also provided at portions facing the other surface acoustic wave resonators on the bonding substrate 329.

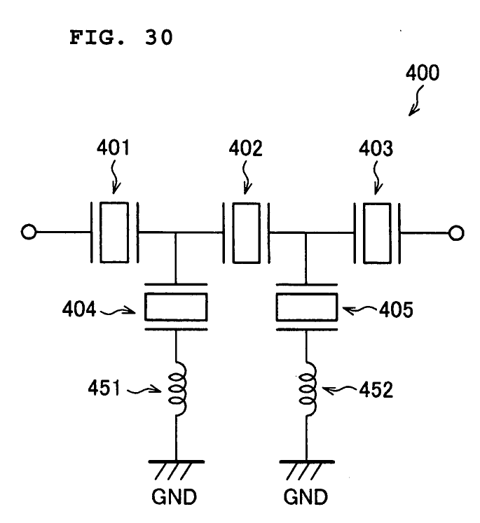

Further, a surface acoustic wave filter according to yet another specific example of the preferred embodiment of the present invention will be described with reference to FIG. 30 through FIG. 34.

FIG. 30 illustrates a circuit diagram of a surface acoustic wave filter 400 according to the above-described specific example. The surface acoustic wave filter 400 includes surface acoustic wave resonators 401 through 405 having IDTs (vibrating portions) arranged in a ladder configuration. Note that the surface acoustic wave resonators 401 through 403 are serial resonators, and the surface acoustic wave resonators 404 and 405 are parallel resonators, with inductors 451 and 452 being serially connected to the surface acoustic wave resonators 404 and 405.

The following is a description with reference to FIG. 31 through FIG. 34, with regard to the surface acoustic wave filter 400 according to the above-described specific example.

First, as shown in FIG. 31, surface acoustic wave resonators 401 through 405 and lead wiring (element wiring) 408 through 415 are formed on a piezoelectric substrate 1, thereby fabricating a SAW element 450.

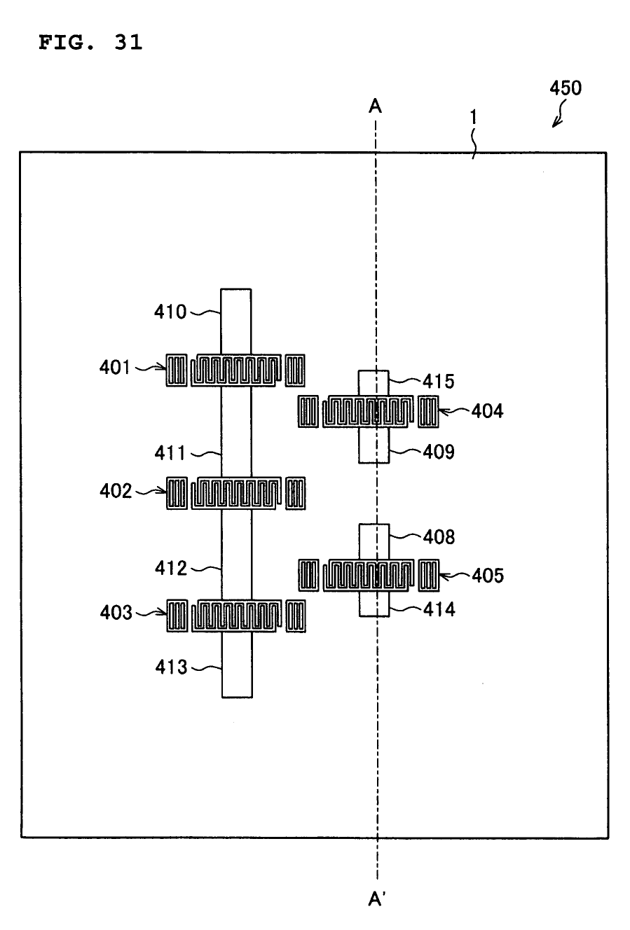

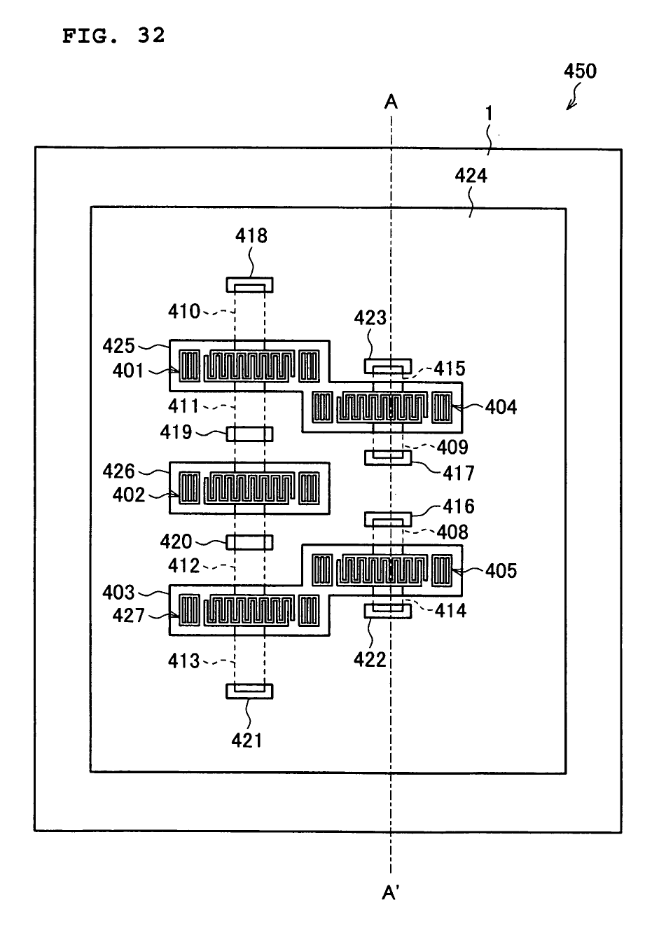

Next, as shown in FIG. 32, a resin layer 424 is formed on the SAW element 450, having resin layer openings 416 through 423 for exposing a portion of the lead wiring 408 through 415, and resin layer openings 425 through 427 for exposing the surface acoustic wave resonators 401 through 405. The resin layer 424 may also cover substantially the entire piezoelectric substrate 1.

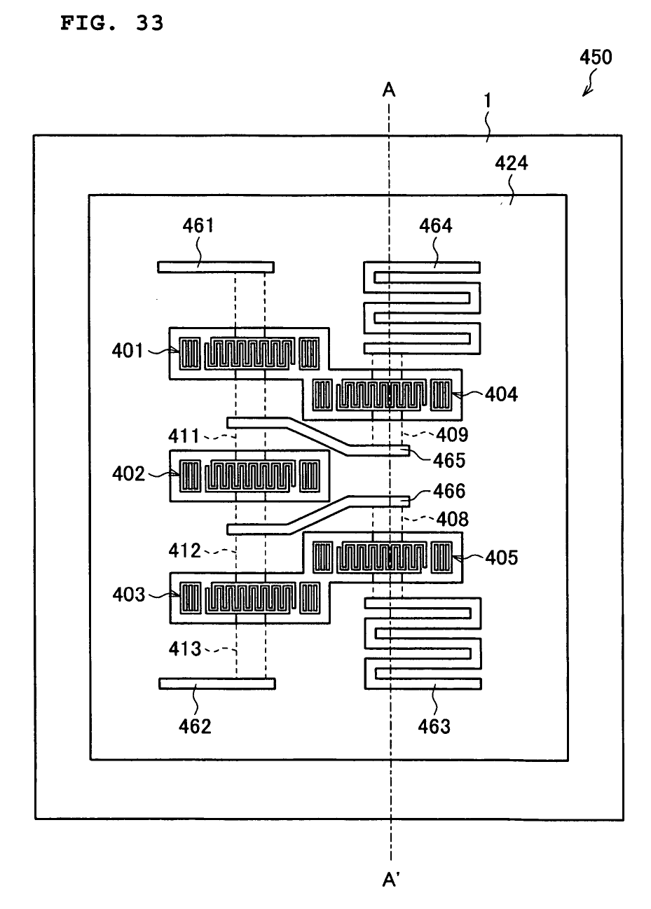

Next, as shown in FIG. 33, first wiring 461 through 464, connected to the lead wiring 410, 413, 414, and 415 via the resin openings 418, 421, 422, and 423, is formed. Note that the first wiring 463 and 434 is formed integrally with inductors L. The inductors L on the first wiring 463 and 464 corresponds to the above inductors 451 and 452. Although the first wiring includes inductors L in the description above, the first wiring may include a capacitance C. Further, first wiring 465 connected to the lead wiring 409 and 411 via the resin openings 417 and 419, and first wiring 466 connected to the lead wiring 408 and 412 via the resin openings 416 and 420 are formed. In addition, the width of the lead wiring 408 through 415 may be increased, or a portion of the bus bar for the surface acoustic wave resonators 401 through 405 may be formed with wiring, thereby improving the connection between the lead wiring 408 through 415, the bus bar, and the first wiring 461 through 466.

Next, as shown in FIG. 34, a bonding substrate 432 in which through holes 428 through 431 have been formed is positioned and bonded onto the resin layer 424 such that the ends of the first wiring 461 through 464 are exposed, and the resin layer 424 and the bonding substrate 432 are bonded by an unshown adhesive layer. External terminals 433 through 436 are then formed so as to be connected to the first wiring 461 through 464 via the through holes 428 through 431, thereby completing the surface acoustic wave filter 400. The portions of the external terminals 433 through 436 which are formed at the through holes 428 through 431 define external terminal connecting material. That is to say, the external terminals 433 through 436 are configured such that the external terminal connecting material and the external terminals are integrally formed. The external terminal connecting material and the external terminals 433 through 436 are formed by filling the through holes 428 through 431 with Au-Sn solder using a printing technique, for example, and treating with heat. Also, the external terminals may be thin films formed by a lift-off process. Also, the external terminal connecting material and the external terminals may be separately formed using different methods.

For the surface acoustic wave resonators 404 and 405 of the SAW element 450 in the surface acoustic wave filter 400, a protective space for the IDTs of the surface acoustic wave resonators is provided by the thickness of the resin layer 424. In the same manner, for the surface acoustic wave resonators 401 through 403, a protective space for the IDTs of the surface acoustic wave resonators is provided by the thickness of the resin layer. Also, the protective space may be provided by recesses at the portions of the bonding substrate 432 facing the surface acoustic wave resonators 401 through 405.

### Seventh Preferred Embodiment

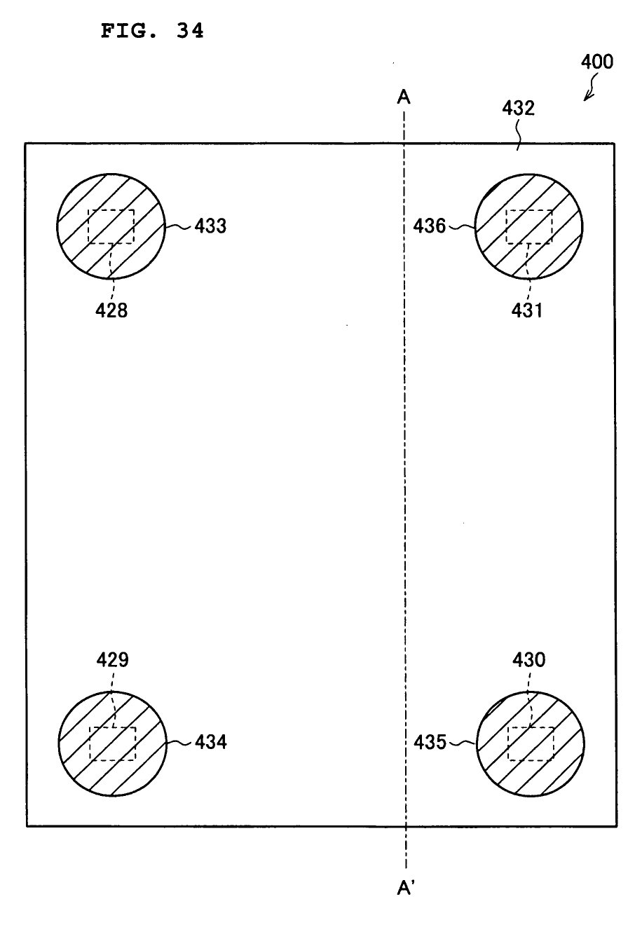

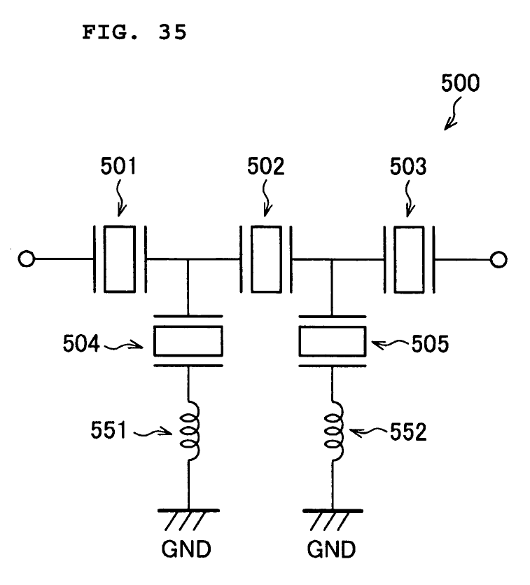

Another preferred embodiment of the present invention will be described with reference to FIG. 35 through FIG. 48. Note that in order to facilitate description, elements having the same functions as elements illustrated in the above first through sixth preferred embodiments will be denoted with the same reference numerals, and description thereof will be omitted.

A surface acoustic wave filter according to the present preferred embodiment will be described with reference to FIG. 35 through FIG. 48.

FIG. 35 illustrates a circuit diagram of a surface acoustic wave filter 500 according to the present preferred embodiment. The surface acoustic wave filter 500 includes surface acoustic wave resonators 501 through 505 having IDTs (vibrating portions) arranged in a ladder configuration. Note that the surface acoustic wave resonators 501 through 503 are serial resonators, and the surface acoustic wave resonators 504 and 505 are parallel resonators, with inductors 551 and 552 being serially connected to the surface acoustic wave resonators 504 and 505.

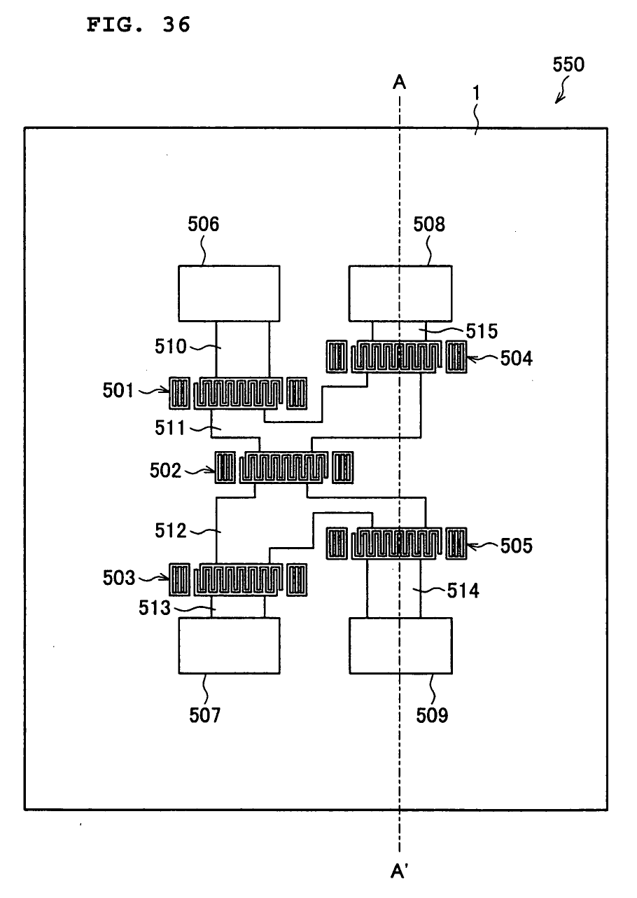

First, as shown in FIG. 36, surface acoustic wave resonators 501 through 505, electroconductive pads (element wiring) 506 through 509, and lead wiring (element wiring) 510 through 515 are formed on a piezoelectric substrate 1, thereby fabricating a SAW element 550.

With the present preferred embodiment, a piezoelectric substrate of LiTaO3 which is about 0.35 mm thick is used for the piezoelectric substrate 1. The surface acoustic wave resonators 501 through 505 are formed of comb electrodes and reflectors of a metal, such as Al. Further, the electroconductive pads (element wiring) 506 through 509 and lead wiring (element wiring) 510 through 515 are also formed of a metal, such as Al. The surface acoustic wave resonators 501 through 505, electroconductive pads (element wiring) 506 through 509, and lead wiring (element wiring) 510 through 515, are formed by the lift-off method by vapor deposition. Also, multiple combinations of the surface acoustic wave resonators 501 through 505, electroconductive pads (element wiring) 506 through 509, and lead wiring (element wiring) 510 through 515, may be formed on the piezoelectric substrate 1, thereby forming a group substrate of multiple SAW elements. In the event that a group substrate of SAW elements is formed, alignment marks are also formed on the piezoelectric substrate 1. Formation of the surface acoustic wave resonators 501 through 505, electroconductive pads (element wiring) 506 through 509, and lead wiring (element wiring) 510 through 515, and alignment marks can be performed with the same process. Subsequently, a protective film of SiN or SiO2 or other suitable material is preferably formed to a thickness of about 5 nm at the portion of the comb electrodes and reflectors of the surface acoustic wave resonators 501 through 505.

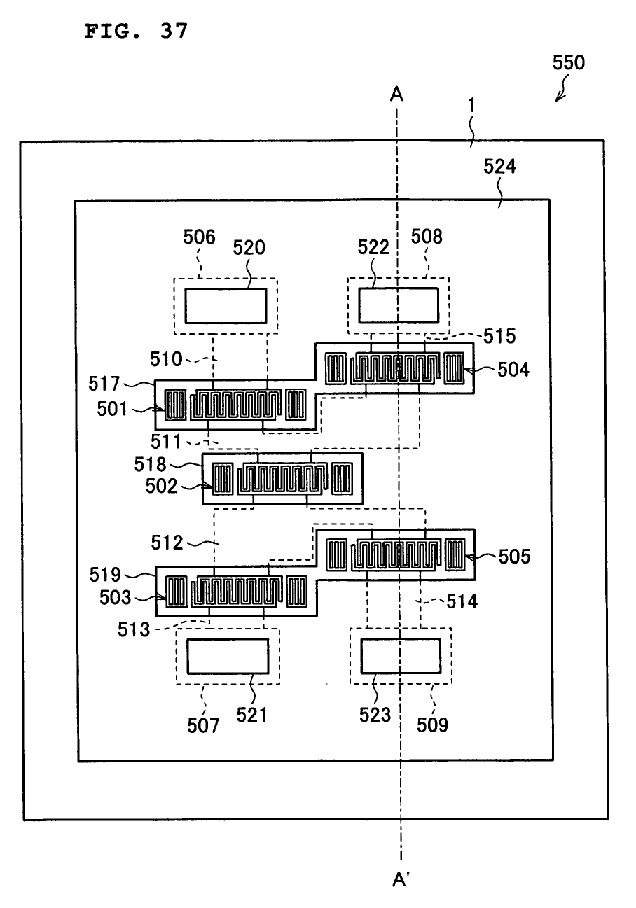

Next, as shown in FIG. 37, a resin layer 524 is formed on the SAW element 550, the resin layer 524 includes resin layer openings 517 through 519 for exposing the surface acoustic wave resonators 501 through 505, and resin layer openings 520 through 523 for exposing the electroconductive pads 506 through 509. The resin layer 524 may cover substantially the entire piezoelectric substrate 1.

The resin layer 524 is preferably formed by applying photosensitive polyimide to a thickness of about 10 μm, for example, and exposing and developing so as to form the resin layer openings 517 through 523. Also, the resin layer openings 517 through 523 may be formed such that not only the surface acoustic wave resonators 501 through 505 but also the nearest portions of the lead wiring 510 through 515 connected to the surface acoustic wave resonators 501 through 505 are exposed.

Also, the exposing conditions are preferably optimized at this time such that the resin openings 520 through 523 have tapered shapes. Thus, latter formation of wiring by metal vapor deposition or electroconductive paste at the resin layer openings 520 through 523 is facilitated.

Also, where the article is a group substrate of SAW elements, the resin layer 524 includes openings at the dicing line portions. No resin at the dicing line portions suppresses clogging at the time of dicing. Also, the opening width of dicing line portions is preferably approximately equal to the width of the dicing blade.

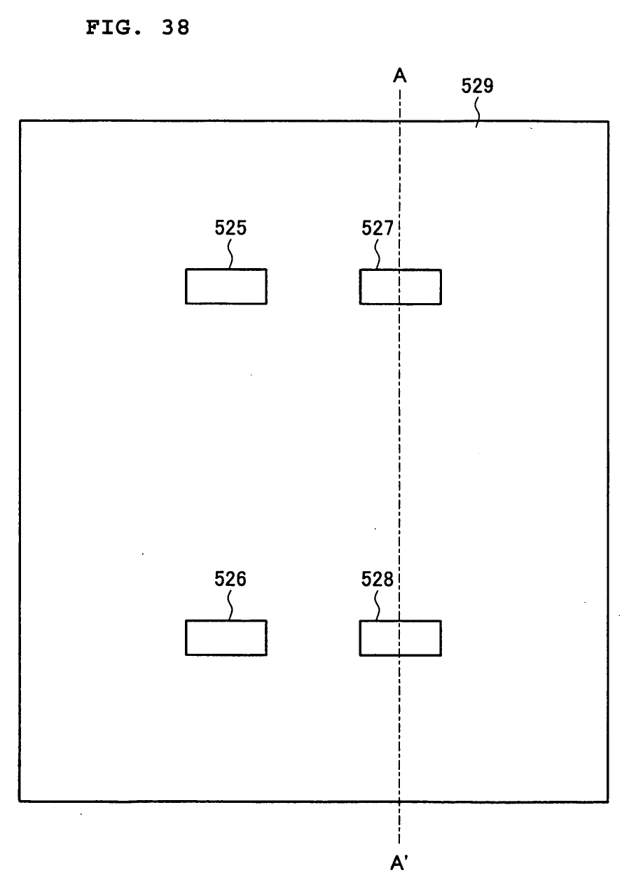

Next, as shown in FIG. 38, the bonding substrate 529 in which through holes 525 through 528 have been formed such that the electroconductive pads 506 through 509 are exposed through the resin openings 520 through 523, is positioned and bonded onto the SAW element 550.

A glass substrate is an example of the suitable bonding substrate 529. A glass substrate that is about 100 μm thick can be used. At the time of bonding, an adhesive agent is applied to substantially the entire surface of the bonding substrate 529 to form an adhesive layer (not shown) which is bonded to the resin layer 524, and the adhesive agent is hardened.

Also, a glass substrate may be used for the bonding substrate 529, with the through holes 525 through 528 being formed after bonding to the resin layer 524. In this case, patterning of the through holes is not performed on the bonding substrate 529 (glass substrate) such that positioning is not required. Also, at the time of forming the through holes 525 through 528, alignment marks on the piezoelectric substrate 1 are used to form tapered through holes 525 through 528 in the glass substrate with a laser, corresponding to the electroconductive pads 506 through 509 on the piezoelectric substrate 1. At this time, the adhesive agent is also removed by the laser. However, in this case, a resist is preferably applied to substantially the entire surface of the glass substrate and subjected to hydrofluoric acid treatment following the laser process. Processing with laser causes fused material called dross to adhere. The dross is removed by the hydrofluoric acid.

Next, as shown in FIG. 39, second wiring 530 through 533 connected to the electroconductive pads 506 through 509 via the resin openings 520 through 523 and the through holes 525 through 528 are formed on the bonding substrate 529. Note that the second wiring 532 and 533 includes inductors L. The inductors L on the second wiring 532 and 533 correspond to the inductors 551 and 552. While the second wiring preferably includes inductors L in the description above, the second wiring may include a capacitance C.

The second wiring 530 through 533 is formed on the bonding substrate 529 by a lift-off process, for example. The structure of the second wiring 530 through 533 is preferably Au (100 nm)/Ti (20 nm)/Al electrode (1 μm)/Ti (100 nm), for example.

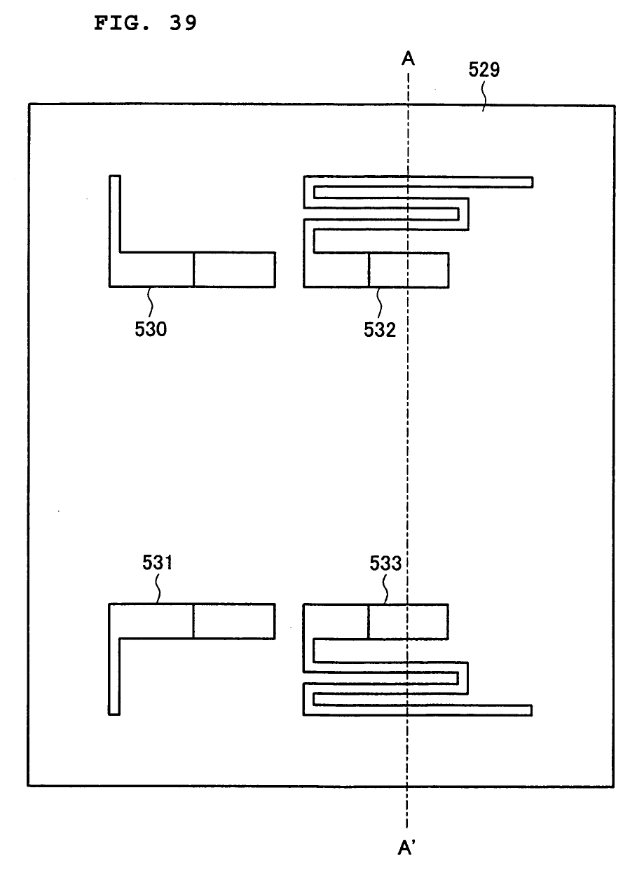

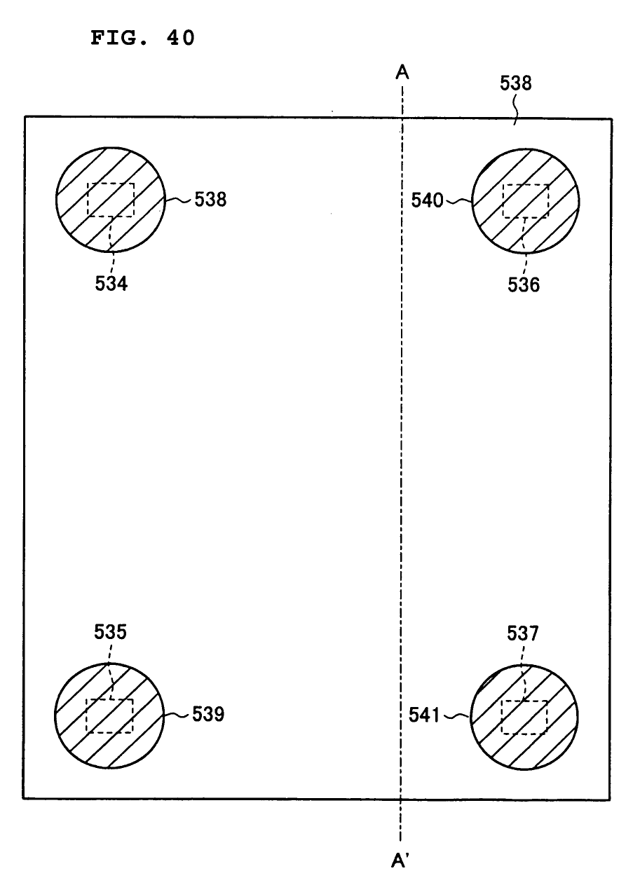

Next, as shown in FIG. 40, an upper resin layer (upper insulating layer, insulating pattern) 538 is formed on the bonding substrate 529 wherein upper resin layer openings 534 through 537 are formed such that the ends of the second wiring 530 through 533 are exposed. Examples of material used for the upper resin layer include photosensitive polyimide, benzo-cyclo-butene, cyclic olefin resins, epoxy resins, and other suitable materials. External terminals 538 through 541 are then formed so as to be connected to the ends of the second wiring 530 through 533 via the upper resin openings 534 through 537, thereby completing the surface acoustic wave filter 500. The portions of the external terminals 538 through 541 which are formed at the upper resin openings 534 through 537 define external terminal connecting material. That is to say, the external terminals 538 through 541 are configured such that the external terminal connecting material and the external terminals are integrally formed. The external terminal connecting material and the external terminals are formed by filling the upper resin openings 534 through 537 with Au-Sn solder using a printing technique, for example, and treating with heat. Alternatively, the external terminals may be thin films formed by lift-off. Also, the external terminal connecting material and the external terminals may be separately formed using different methods.

Further, an electroconductive resin for absorbing shock is preferably coated on the rear side of the piezoelectric substrate and hardened, as in the first preferred embodiment. Alternatively, a metal film may be formed on the rear side of the piezoelectric substrate beforehand, with the shock-absorbing resin coated thereupon. The electroconductive resin or metal provides an electromagnetic wave shielding effect.

Also, in the event that the article is a group substrate of SAW elements, dicing is performed, thereby completing individual surface acoustic wave devices.

As described above, the position of the electroconductive pads and the external terminals can be easily offset, such that the degree of freedom in design of the surface acoustic wave filter is improved.

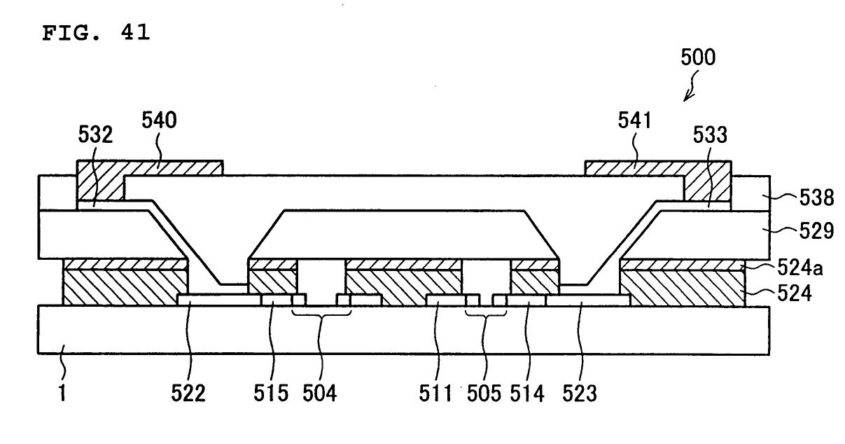

Now, a cross-sectional view along line A-A′ shown in FIG. 36 through FIG. 40 of the completed surface acoustic wave filter 500 is shown in FIG. 41.

As shown in FIG. 41, an adhesive layer 524a is formed between the resin layer 524 and the bonding substrate 529 of the surface acoustic wave filter 500. Also, for the surface acoustic wave resonators 504 and 505 of the SAW element 550, a protective space for the IDTs of the surface acoustic wave resonators is provided by the thickness of the resin layer 524. In the same manner, for the surface acoustic wave resonators 501 through 503, a protective space for the IDTs of the surface acoustic wave resonators is provided by the thickness of the resin layer.

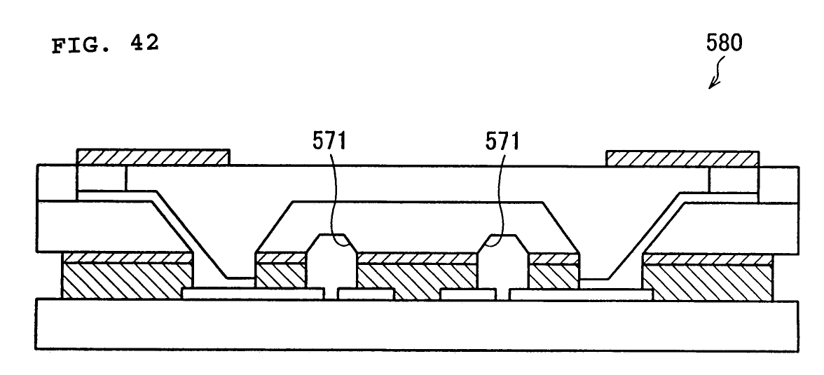

Further, a surface acoustic wave filter 580, which is a modification of the above-described surface acoustic wave filter 500, will be described with reference to FIG. 42. This surface acoustic wave filter 580 includes recesses 570 and 571 provided at portions facing the IDTs of the surface acoustic wave resonators 504 and 505 on the bonding substrate 529 of the surface acoustic wave filter 500. Moreover, recesses are also provided at portions facing the IDTs of the other surface acoustic wave resonators on the bonding substrate 529.

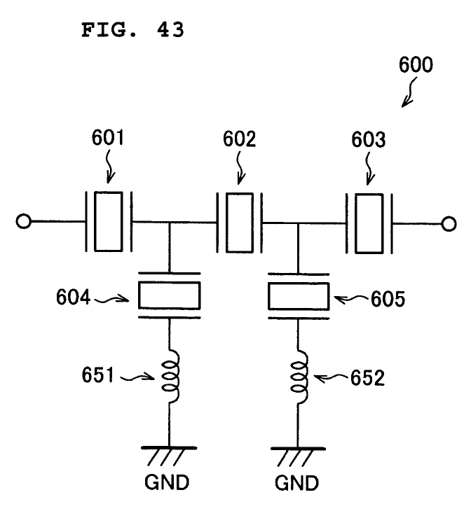

Further, a surface acoustic wave filter according to yet another specific example of the preferred embodiments of the present invention will be described with reference to FIG. 43 through FIG. 48.

FIG. 43 illustrates a circuit diagram of a surface acoustic wave filter 600 according to the specific example. The surface acoustic wave filter 600 includes surface acoustic wave resonators 601 through 605 having IDTs (vibrating portions) arranged in a ladder configuration. Note that the surface acoustic wave resonators 601 through 603 are serial resonators, and the surface acoustic wave resonators 604 and 605 are parallel resonators, with inductors 651 and 652 being serially connected to the surface acoustic wave resonators 604 and 605.

First, as shown in FIG. 44, surface acoustic wave resonators 601 through 605 and lead wiring (element wiring) 606 through 613 are formed on a piezoelectric substrate 1, thereby fabricating a SAW element 650.

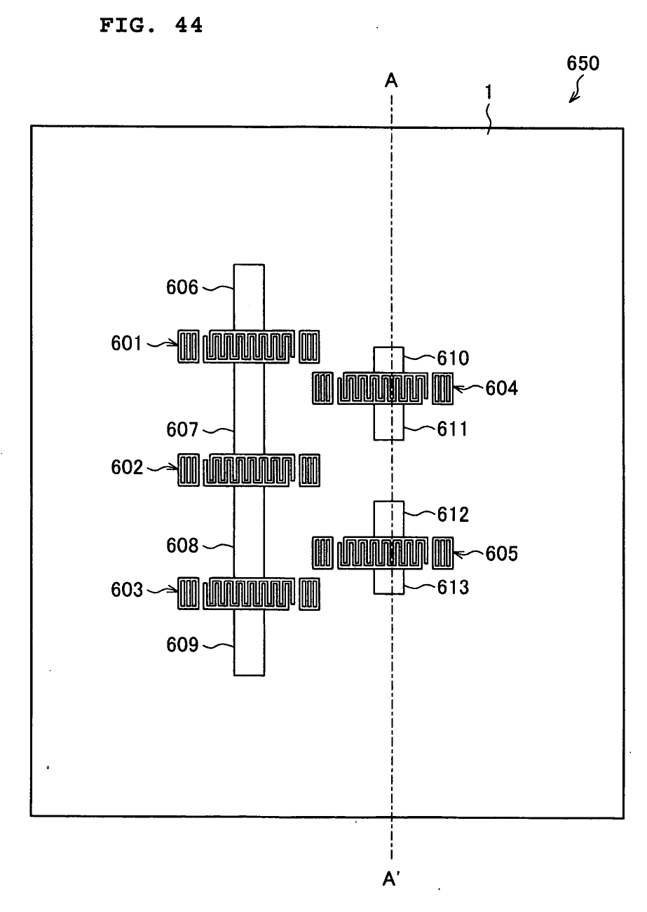

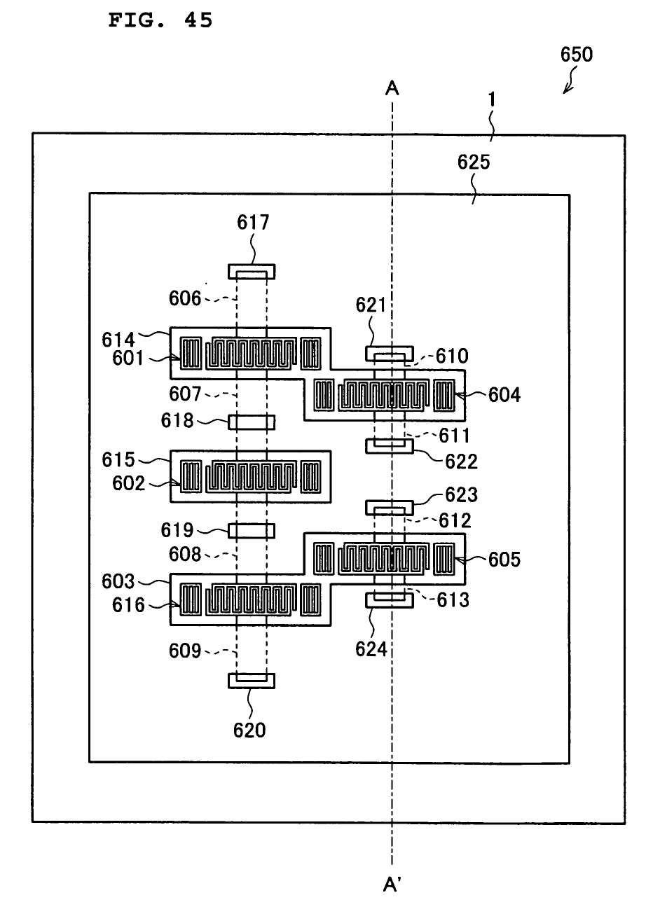

Next, as shown in FIG. 45, a resin layer 625 is formed on the SAW element 650, the resin layer 625 includes resin layer openings 614 through 616 for exposing the surface acoustic wave resonators 601 through 605, and resin layer openings 617 through 624 for exposing the lead wiring 606 through 613. The resin layer 625 may also cover substantially the entire piezoelectric substrate 1.

Next, as shown in FIG. 46, a bonding substrate 634 in which through holes 626 through 633 have been formed is positioned and bonded onto the resin layer 625 such that the lead wiring 606 through 613 is exposed via resin openings 617 through 624 to thereby bond the resin layer 625 and the bonding substrate 634. At this time, an unshown adhesive layer is formed on the resin layer 625. Then, second wiring 635 through 638 which connect to the lead wiring 606, 609, 610, and 613 via the resin openings 617, 620, 621, and 624, and the through holes 626, 629, 630, and 633 are formed. For example, the second wiring 635 through 638 is formed by filling in the resin openings 617, 620, 621, and 624 and the through holes 626, 629, 630, and 633 with electroconductive paste, and forming wiring with the electroconductive paste. Note that the second wiring 637 and 638 is formed integrally with inductors L. The inductors L on the second wiring 637 and 638 correspond to the above-described inductors 651 and 652. While the second wiring has inductors L in the description above, the second wiring may have a capacitance C. Further, second wiring 639 connected to the lead wiring 607 and 611 via the resin openings 618 and 622 and through holes 627 and 631, and second wiring 640 connected to the lead wiring 608 and 612 via the resin openings 619 and 623 and through holes 628 and 632 are formed.

Next, as shown in FIG. 47, an upper resin layer (upper insulating layer) 645 is formed on the bonding substrate 634. Upper resin layer openings 641 through 644 are formed in the upper resin layer 645 such that the ends of the second wiring 635 through 638 are exposed. External terminals 646 through 649 are then formed so as to be connected to the second wiring 635 through 638 via the upper resin layer openings 641 through 644, thereby completing the surface acoustic wave filter 600.

Also, in some cases, the width of the lead wiring 606 through 613 may be increased, or a portion of the bus bar for the surface acoustic wave resonators 601 through 605 may include wiring, thereby improving the connection between the lead wiring 606 through 613, the bus bar, and the second wiring 635 through 640.

The portions of the external terminals 646 through 649 which are formed at the upper resin layer openings 641 through 644 define external terminal connecting material. That is to say, the external terminals 646 through 649 are configured such that the external terminal connecting material and the external terminals are integrally formed. The external terminal connecting material and the external terminals is formed by filling the upper resin layer openings 641 through 644 with Au—Sn solder using a printing technique, for example, and treating with heat. Alternatively, the external terminals may be thin films formed by a lift-off process. Also, the external terminal connecting material and the external terminals may be separately formed using different methods.

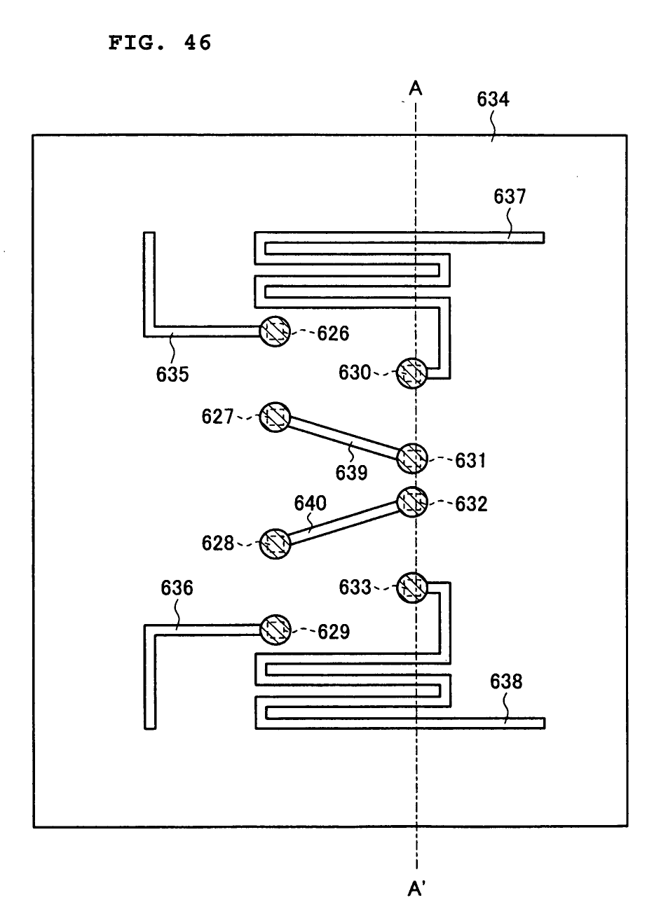

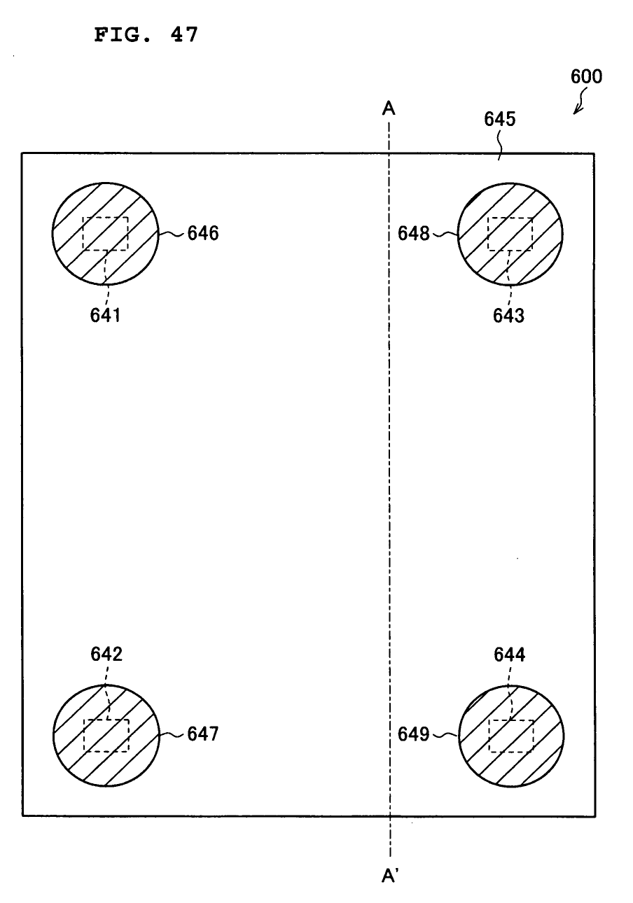

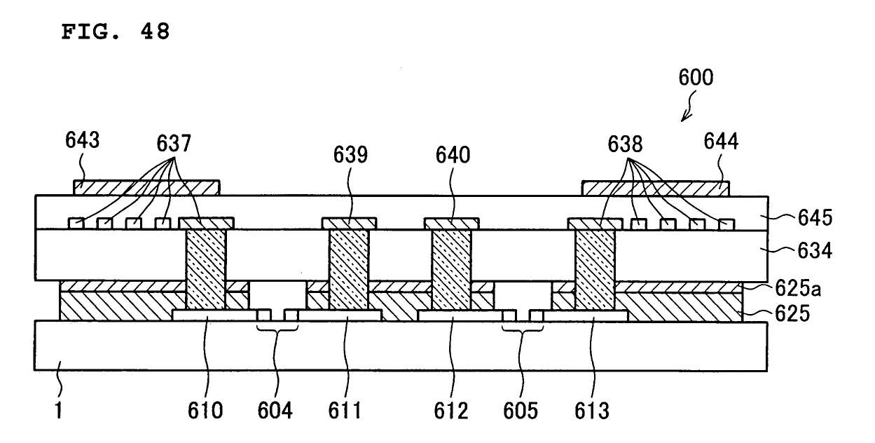

Now, a cross-sectional view along line A-A′ shown in FIG. 44 through FIG. 47 of the completed surface acoustic wave filter 600 is shown in FIG. 48.

As shown in FIG. 48, an adhesive layer 625a is formed between the resin layer 625 and the bonding substrate 634 of the surface acoustic wave filter 600. For the surface acoustic wave resonators 604 and 605 of the SAW element 650, a protective space for the IDTs of the surface acoustic wave resonators is provided by the thickness of the resin layer 625. In the same manner, for the surface acoustic wave resonators 601 through 603, a protective space for the IDTs of the surface acoustic wave resonators is provided by the thickness of the resin layer. Also, the protective space may be provided by recesses at the portions of the bonding substrate 634 facing the surface acoustic wave resonators 601 through 605. Also, the recesses may be formed at the same time that the through holes 626 through 633 are formed in the bonding substrate 634.

While IDTs, reflectors, lead wiring, and electroconductive pads are preferably formed on the piezoelectric substrate for the surface acoustic wave filter according to the above-described first through seventh preferred embodiments, only the IDTs and reflectors may are formed on the piezoelectric substrate 1. In this case, resin openings are provided in the resin layer for exposing the IDT bus bar, and the wiring are formed on the resin layer or on the bonding substrate. Accordingly, a portion of the wiring is eliminated, thereby reducing the size of the surface acoustic wave filter.

Also, while the positions of the resin openings, through holes, and upper resin openings are offset in the above-described first through seventh preferred embodiments, the positions of the resin openings, through holes, and upper resin openings may be aligned. This eliminates the electroconductive pads and a portion of the wiring, thereby reducing the size of the surface acoustic wave filter.

### Eighth Preferred Embodiment

While a SAW element has been described as a piezoelectric element in the above-described first through seventh preferred embodiments, a piezoelectric thin-film element may be used instead of the SAW element in the above-described first through seventh preferred embodiments.

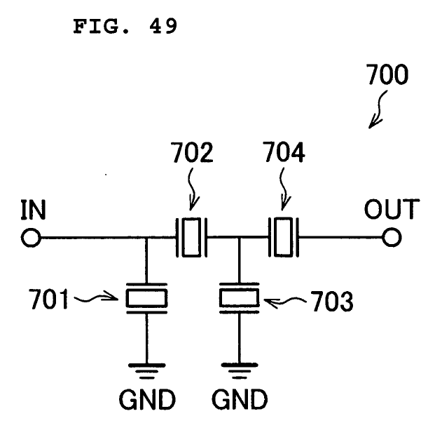

An example of a piezoelectric thin-film filter (piezoelectric device) using the piezoelectric thin-film element will be described with reference to FIG. 49 through FIG. 56.

FIG. 49 illustrates a circuit diagram of the piezoelectric thin-film filter 700 according to the present preferred embodiment. The piezoelectric thin-film filter 700 includes piezoelectric thin-film resonators 701 through 704 (vibrating portions) arranged in a ladder configuration. Note that, with the piezoelectric thin-film filter 700, the piezoelectric thin-film resonators 701 and 703 are serial resonators, and the piezoelectric thin-film resonators 702 and 704 are parallel resonators.

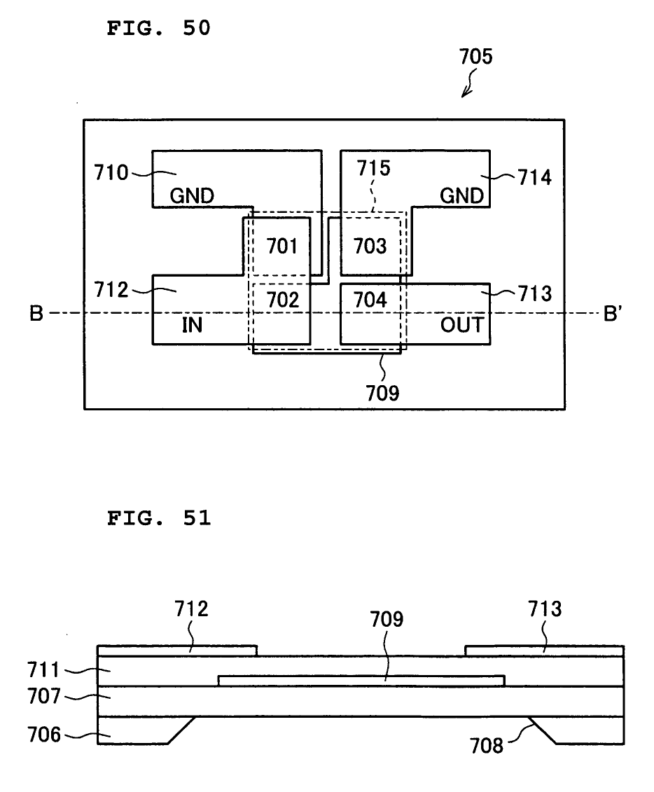

The method for manufacturing the piezoelectric thin-film filter 700 will be described with reference to FIG. 50 through FIG. 55. This manufacturing method is preferably the manufacturing method according to the seventh preferred embodiment, in which the piezoelectric thin-film element replaces the surface acoustic wave element.

First, as shown in FIG. 50 and FIG. 51, a piezoelectric thin-film element (piezoelectric element) 705 including the piezoelectric thin-film resonators 701 through 704 is fabricated. The piezoelectric thin-film element 705 includes a supporting substrate 706 preferably formed of silicon, and an insulating film 707 formed thereon of a layer of SiO2, SiO2 and Al2O3, or a layer of Al2O3 and SiO2. Further, the supporting substrate 706 includes an opening (hollow portion) 708 which passes through the supporting substrate 706 in the thickness direction and extends to the insulating film 707. Also, formed upon the insulating film 707 are, in order, lower electrodes (electrodes) 709 and 710 which are formed of Al or other suitable material, a piezoelectric thin film 711 formed of ZnO or AlN or other suitable material, and upper electrodes (electrodes) 712, 713, and 714, formed of Al or other suitable material. The insulating film 707 defines a diaphragm. This diaphragm faces the opening (hollow portion) 708. The piezoelectric thin-film resonators 701 through 704 sandwich the upper and lower surfaces of a thin film portion having at least one layer of piezoelectric film on the diaphragm with a pair of lower electrode and upper electrode facing one another. With the configuration according to the present preferred embodiment, the upper electrodes of the piezoelectric thin-film resonators 701 and 702 are integrated to define the upper electrode 712. The lower electrode 710 of the piezoelectric thin-film resonator 701 is grounded. The lower electrodes of the piezoelectric thin-film resonators 702 and 704 are integrated to define the lower electrode 709. The upper electrode 714 of the piezoelectric thin-film resonator 703 is grounded. The upper electrode of the piezoelectric thin-film resonator 704 is the upper electrode 713. Also, the dotted line 715 indicates the diaphragm of this piezoelectric thin-film element 705. Note that the piezoelectric thin film 711 is omitted in FIG. 50.

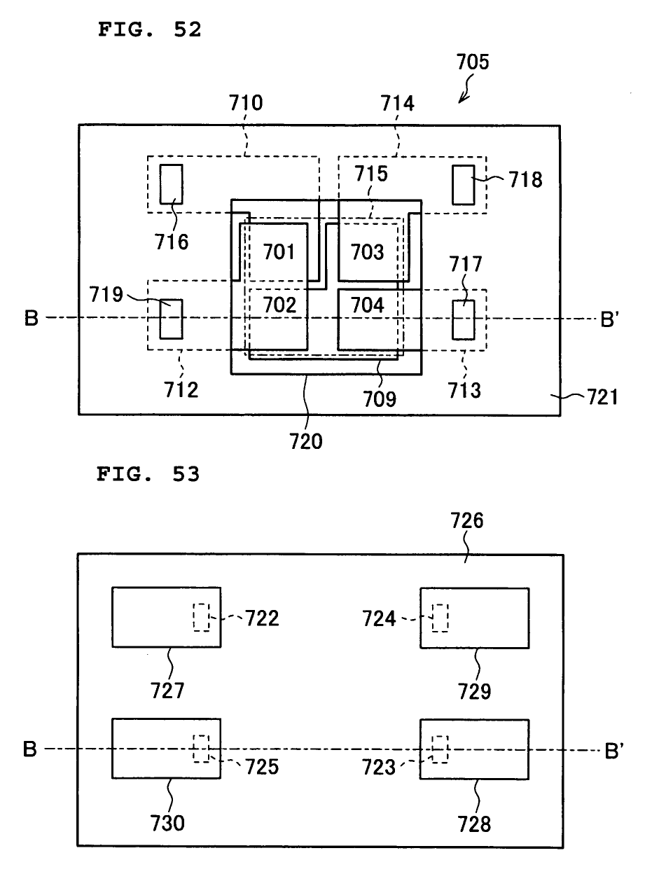

Next, as shown in FIG. 52, a resin layer 721 having resin openings 719, 717, and 718 are formed on the piezoelectric thin-film element 705, from which the upper electrodes 712, 713, and 714 are exposed, a resin opening 716 from which the lower electrode 710 is exposed, and resin openings 720 from which are exposed the piezoelectric thin-film resonators 701 through 704.

Next, as shown in FIG. 53, a bonding substrate 726 including through holes 725, 723, and 724, from which the upper electrodes 712, 713, and 714 are exposed through the resin openings 719, 717, and 718, and a through hole 722 through which the lower electrode 710 is exposed through the resin opening 716 are positioned and bonded to the resin layer 721 by an unshown adhesive layer. Second wiring 727 through 730 are then formed on the bonding substrate 726 so as to connect with the upper electrode 710, lower electrode 712, and upper electrodes 713 and 714, through the resin openings 716 through 719 and the through holes 722 through 725. Note that this second wiring 727 through 730 may include inductors L or a capacitance C. Also, regarding the bonding substrate 726, a substrate which has a linear expansion coefficient similar to that of the supporting substrate 706 is preferable, such as a hardened glass substrate. Similar linear expansion coefficients between the supporting substrate 706 and the bonding substrate 726 prevent and minimize the occurrences of stress, warping, and distortion. Accordingly, effects on the piezoelectric thin-film filter being manufactured are suppressed, and the reliability of the properties and the bonding strength are improved.

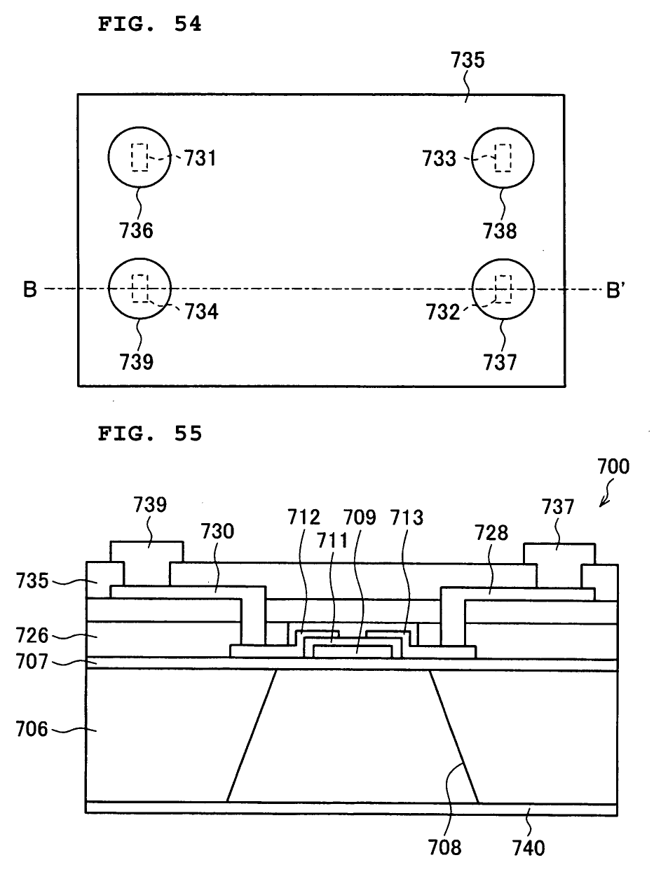

Next, as shown in FIG. 54, an upper resin layer 735 is formed on the bonding substrate 726, the upper resin layer 735 includes upper resin openings 731 through 734 such that the ends of the second wiring 727 through 730 that are exposed. External terminals 736 through 739 are then formed so as to contact the second wiring 727 through 730 through the upper resin openings 731 through 734. Note that the portions of the external terminals 736 through 739 which are formed at the upper resin layer openings 731 through 734 defines an external terminal connecting material. That is to say, the external terminals 736 through 739 are configured such that the external terminal connecting material and the external terminals are integrally formed. The external terminal connecting material and the external terminals 736 through 739 are formed by filling the upper resin layer openings 731 through 734 with Au-Sn solder using a printing technique, and treating with heat. Alternatively, the external terminal connecting material and the external terminals 736 through 739 may be thin films formed by a lift-off process. Also, the external terminal connecting material and the external terminals 736 through 739 may be separately formed using different methods.

Further, an alumina lid member is attached so as to cover the opening 708 of the supporting substrate 706 shown in FIG. 51, thereby completing the piezoelectric thin-film filter 700.

Now, a cross-sectional view along line B-B′ shown in FIG. 50 through FIG. 54 of the completed piezoelectric thin-film filter 700 is shown in FIG. 55.

As shown in FIG. 55, with this piezoelectric thin-film filter 700, a protective space for the piezoelectric thin-film resonators 702 and 704 of the piezoelectric thin-film element 705 is provided by the thickness of the resin layer 726. In the same manner, a protective space for the piezoelectric thin-film resonators 701 and 703 is provided by the thickness of the resin layer 726.

While the present preferred embodiment describes a protective space being provided by the thickness of the resin layer, the protective space may be provided by forming recesses in the bonding substrate.

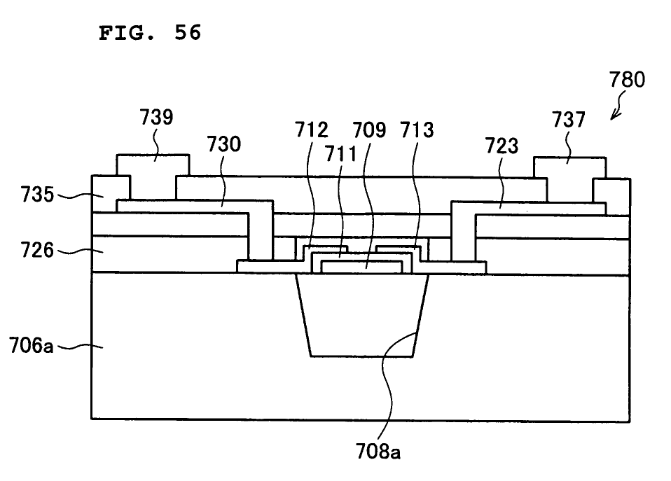

Also, as a modification of the piezoelectric thin-film filter 700, a piezoelectric thin-film filter 780 is shown in FIG. 56, for example. As shown in FIG. 56, the piezoelectric thin-film filter 780 includes the supporting substrate 706 of the piezoelectric thin-film filter 700 to which the opening 708 is provided, is replaced with a supporting substrate 706a in which a recess 708a is provided. With this piezoelectric thin-film filter 780, the diaphragm is provided by the recess 708. Also, the diaphragm is covered by the recess 708, such that a lid member is not required as in the piezoelectric thin-film filter 700.

Also, as a further modification of the piezoelectric thin-film filter, a piezoelectric thin-film resonator may include neither an opening nor a recess formed in the supporting substrate, and a space is formed between the lower electrode and supporting substrate.

The present invention is not restricted to the above-described preferred embodiments, but rather various changes may be made within the range set forth in the claims, and further, preferred embodiments obtained by suitably combining the technical means disclosed in different preferred embodiments are also within the technical scope of the present invention.

According to various preferred embodiments of the present invention, a piezoelectric device such as a surface acoustic wave device and a piezoelectric thin-film filter for use, for example, for delay lines, filters, and other suitable device is greatly reduced in size. Also, communication devices such as cellular telephones and other suitable communication devices using the piezoelectric device are reduced in size.

What is claimed is:

1. A piezoelectric device comprising:
a piezoelectric element including at least one vibrating portion provided on a substrate and element wiring connected to said vibrating portion;
a bonding substrate including through holes and bonded by an adhesive layer to the piezoelectric element so as to face said vibrating portion;
a protective space for said vibrating portion; and
first wiring provided between said adhesive layer and said bonding substrate which is connected to said element wiring; wherein
said first wiring and external terminals are connected via external terminal connecting material provided in said through holes.

2. A piezoelectric device according to claim 1, wherein said first wiring includes at least one of a capacitance and an inductor.
